(19) United States
(12) Patent Application Publication
(10) Pub. No.: US 2025/0056976 A1
(43) Pub. Date: Feb. 13, 2025

(54) Display Panel and Display Device

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Shuo Li, Beijing (CN); Youchun Chen, Beijing (CN); Yanyang Shang, Beijing (CN); Zhenglong Yan, Beijing (CN)

(21) Appl. No.: 18/933,428

(22) Filed: Oct. 31, 2024

Related U.S. Application Data
(63) Continuation of application No. 18/834,852, filed on Jan. 1, 0001.

(30) Foreign Application Priority Data
Jul. 22, 2022 (CN) 202210870995.1

(51) Int. Cl. H10K 59/122; H10K 59/131; H10K 59/80

(52) U.S. Cl. CPC H10K 59/122; H10K 59/131; H10K 59/8792

(57) ABSTRACT

A display panel includes a substrate, a first electrode layer disposed on the substrate, and a light-emitting definition layer disposed on a side of the first electrode layer away from the substrate. The first electrode layer includes first electrode blocks and second electrode blocks. An area of a first electrode block is greater than an area of a second electrode block. The first electrode blocks are arranged in an array of rows and columns. Each second electrode block is located between four adjacent first electrode blocks arranged in two rows and two columns. The light-emitting definition layer has first light-transmitting holes. At least a part of each first electrode block is exposed by a first light-transmitting hole, and at least a part of each second electrode block is exposed by a first light-transmitting hole. At least part of a boundary of at least one first light-transmitting hole is curved.

### CROSS-REFERENCE TO RELATED APPLICATIONS

This application is a continuation of U.S. Ser. No. 18/834,852, filed on Jul. 20, 2023, which is a U.S. national phase application of International Patent Application No. PCT/CN2023/108330, filed on Jul. 20, 2023, which in turn claims priority to Chinese Patent Application No. 202210870995.1, Jul. 22, 2022, which are incorporated herein by reference in their entirety.

### TECHNICAL FIELD

The present disclosure relates to the field of display technologies, and in particular, to a display panel and a display device.

### BACKGROUND

With the rapid development of display technologies, display devices have gradually come throughout people's lives. Organic light-emitting diodes (OLEDs) are widely used in mobile phones, televisions, notebook computers, or other smart products due to their advantages of self-luminous, low power consumption, wide viewing angle, fast response speed, high contrast, and flexible display.

### SUMMARY

In an aspect, a display panel is provided. The display panel includes a substrate, a first electrode layer, and a light-emitting definition layer. The first electrode layer is disposed on a side of the substrate. The first electrode layer includes a plurality of first electrode blocks and a plurality of second electrode blocks, and an area of a first electrode block is greater than an area of a second electrode block; the plurality of first electrode blocks are arranged in an array of rows and columns, each row includes first electrode blocks arranged in a first direction, and each column includes first electrode blocks arranged in a second direction, the first direction being substantially perpendicular to the second direction; and each second electrode block is located between four adjacent first electrode blocks arranged in two rows and two columns.

The light-emitting definition layer is disposed on a side of the first electrode layer away from the substrate. The light-emitting definition layer has a plurality of first light-transmitting holes, at least a part of each first electrode block is exposed by a first light-transmitting hole, and at least a part of each second electrode block is exposed by a first light-transmitting hole; and at least part of a boundary of at least one first light-transmitting hole is curved.

In some embodiments, the plurality of first light-transmitting holes include a plurality of first light-transmitting sub-holes, a plurality of second light-transmitting sub-holes and a plurality of third light-transmitting sub-holes; a first light-transmitting sub-hole and a third light-transmitting sub-hole each expose at least a part of a first electrode block, and a second light-transmitting sub-hole exposes at least a part of a second electrode block; first light-transmitting sub-holes and third light-transmitting sub-holes are alternately arranged in the first direction; first light-transmitting sub-holes and third light-transmitting sub-holes are alternately arranged in the second direction; a line connecting centers of adjacent first light-transmitting sub-hole and third light-transmitting sub-hole is a first connection line, and a line connecting centers of two first electrode blocks corresponding to the adjacent first light-transmitting sub-hole and third light-transmitting sub-hole is a second connection line; and at least one first connection line is not parallel to a corresponding second connection line.

In some embodiments, among nine first light-transmitting holes corresponding to nine adjacent first electrode blocks that are arranged in three rows and three columns, a line connecting centers of four first light-transmitting holes located at four corners encloses a virtual quadrilateral; the virtual quadrilateral has a first median line extending in the first direction and a second median line extending in the second direction; and the nine first light-transmitting holes are symmetrical with respect to the first median line and/or the second median line.

In some embodiments, one type of light-transmitting sub-holes of first light-transmitting sub-holes and third light-transmitting sub-holes are located at a center and four corners of the virtual quadrilateral; another type of light-transmitting sub-holes of first light-transmitting sub-holes and third light-transmitting sub-holes are located on four sides of the virtual quadrilateral; first light-transmitting holes located at the center and the four corners of the virtual quadrilateral are set light-transmitting holes, and first light-transmitting holes located on the four sides of the virtual quadrilateral are non-set light-transmitting holes; a light-emitting center of a set light-transmitting hole substantially coincides with a center of a corresponding first electrode block; and a light-emitting center of the second light-transmitting sub-hole substantially coincides with a center of a corresponding second electrode block.

Among two non-set light-transmitting holes opposite to each other in the first direction, a center of one non-set light-transmitting hole is located on a first side of a center of a corresponding first electrode block, and a center of another non-set light-transmitting hole is located on a second side of a center of a corresponding first electrode block; among two non-set light-transmitting holes opposite to each other in the second direction, a center of one non-set light-transmitting hole is located on a third side of a center of a corresponding first electrode block, and a center of another non-set light-transmitting hole is located on a fourth side of a center of a corresponding first electrode block; a first side and a second side are two opposite sides of a center of each first electrode block; and a third side and a fourth side are another two opposite sides of the center of each first electrode block.

In some embodiments, the plurality of first light-transmitting holes include a plurality of first light-transmitting sub-holes, a plurality of second light-transmitting sub-holes and a plurality of third light-transmitting sub-holes; an area of a first light-transmitting sub-hole is greater than an area of a third light-transmitting sub-hole; the area of the third light-transmitting sub-hole is greater than an area of a second light-transmitting sub-hole; the first light-transmitting sub-hole and the third light-transmitting sub-hole each expose at least a part of a first electrode block, and the second light-transmitting sub-hole exposes at least a part of a second electrode block; and at least part of a boundary of at least one of the first light-transmitting sub-hole, the second light-transmitting sub-hole and the third light-transmitting sub-hole is curved.

In some embodiments, an outer contour of at least one first light-transmitting hole includes a first curved border and a second curved border, two ends of the first curved border are respectively connected to two ends of the second curved border, and two connection points of the first curved border and the second curved border are a first connection point and a second connection point; a line connecting the first connection point and the second connection point is a first line segment, a length of the first line segment is a maximum dimension of the first light-transmitting hole, and the first line segment divides the first light-transmitting hole into a first sub-portion including the first curved border and a second sub-portion including the second curved border; and an area of the first sub-portion is greater than an area of the second sub-portion.

In some embodiments, the first curved border and the first line segment enclose a semicircle, and the second curved border and the first line segment enclose a semiellipse.

In some embodiments, the plurality of first light-transmitting holes include a plurality of first light-transmitting sub-holes and a plurality of third light-transmitting sub-holes, and an outer contour of a first light-transmitting sub-hole and/or an outer contour of a third light-transmitting sub-hole includes the first curved border and the second curved border.

In some embodiments, the plurality of first light-transmitting holes include second light-transmitting sub-holes, and an outer contour of a second light-transmitting sub-hole is substantially in a shape of a circle or an ellipse.

In some embodiments, an outer contour of at least one first light-transmitting hole includes a first straight border, a second straight border and a third curved border; the first straight border and the second straight border are connected to form a polyline-shaped border; two ends of the third curved border are respectively connected to two ends of the polyline-shaped border; and two connection points connecting the two ends of the third curved border to the polyline-shaped border are a third connection point and a fourth connection point; a line connecting the third connection point and the fourth connection point is a second line segment, a length of the second line segment is a maximum dimension of the first light-transmitting hole, and the second line segment divides the first light-transmitting hole into a third sub-portion including the first straight border and the second straight border and a fourth sub-portion including the third curved border; and an area of the third sub-portion is greater than an area of the fourth sub-portion.

In some embodiments, the third curved border includes a first straight sub-line segment, a first curved sub-line segment and a second straight sub-line segment connected in sequence, the first straight sub-line segment is connected to the first straight border, and the second straight sub-line segment is connected to the second straight border; the first straight sub-line segment is substantially parallel to the second straight border; and the second straight sub-line segment is substantially parallel to the first straight border.

In some embodiments, the plurality of first light-transmitting holes include a plurality of first light-transmitting sub-holes and a plurality of third light-transmitting sub-holes, and the first light-transmitting sub-holes an outer contour of a first light-transmitting sub-hole and/or an outer contour of a third light-transmitting sub-hole includes the first straight border, the second straight border and the third curved border.

In some embodiments, the plurality of first light-transmitting holes include second light-transmitting sub-holes, and an outer contour of a second light-transmitting sub-hole is substantially in a shape of a rhombus.

In some embodiments, an outer contour of the first light-transmitting hole is substantially in a shape of a circle or an ellipse.

In some embodiments, the light-emitting definition layer further has a plurality of second light-transmitting holes; and an orthogonal projection, on the substrate, of each second light-transmitting hole is located between orthogonal projections, on the substrate, of adjacent second electrode blocks in the second direction.

In some embodiments, each of an outer contour of the first electrode block and an outer contour of the second electrode block is substantially in a shape of a polygon; borders of any adjacent first electrode block and second electrode block are opposite and substantially parallel to each other, and a distance between the adjacent first electrode block and second electrode block is substantially equal to a first preset value; and the first preset value is a process limit value at which the first electrode block and the second electrode block are disconnected.

In some embodiments, each of orthogonal projections of the first electrode block and the second electrode block on the substrate is substantially in a shape of a regular octagon.

In some embodiments, the first electrode layer further includes a plurality of first connection strips and a plurality of second connection strips, each first connection strip is electrically connected to a first electrode block, and each second connection strip is electrically connected to a second electrode block; and in the second direction, a single first connection strip and a single second connection strip are arranged between each two adjacent first electrode blocks.

In some embodiments, the display panel further includes a first planarization layer in contact with a surface of the first electrode layer proximate to the substrate, wherein the first planarization layer is provided therein with connection holes, each first connection strip extends into a corresponding connection hole, and each second connection strip extends into a corresponding connection hole. A minimum distance between an orthogonal projection of a boundary of a connection hole on the substrate and an orthogonal projection of a boundary of the first light-transmitting hole on the substrate is greater than or equal to a second preset value.

In some embodiments, the display panel further includes at least one conductive layer disposed between the substrate and the first electrode layer, and the at least one conductive layer includes a plurality of first power signal lines substantially extending in the second direction. An orthogonal projection of at least one first electrode block on the substrate overlaps an orthogonal projection of at least one first power signal line on the substrate; and a region where an orthogonal projection of a first electrode block of the at least one first electrode block overlaps with an orthogonal projection of a first power signal line of the at least one first power signal line on the substrate is symmetrical with respect to a median line of the first electrode block of the at least one first electrode block in the second direction.

In some embodiments, the plurality of first power signal lines include a plurality of first power signal line groups, and each first power signal line group includes two first power signal lines arranged in parallel. An orthogonal projection of a column of first electrode blocks arranged in the second direction on the substrate overlaps with each of orthogonal projections of two first power signal lines in a first power signal line group on the substrate; and the two first power signal lines in the first power signal line group are symmetrical with respect to a median line of the column of first electrode blocks in the second direction.

In some embodiments, the first electrode layer further includes a plurality of first connection strips and a plurality of second connection strips; the first power signal line includes first line portions and second line portions, an orthogonal projection of a first line portion on the substrate is located within the orthogonal projection of the first electrode block on the substrate, and a second line portion is located between two adjacent first electrode blocks in the second direction; and orthogonal projections of a single first connection strip and a single second connection strip on the substrate are located between orthogonal projections of second line portions of two first power signal lines in a single first power signal line group on the substrate.

In some embodiments, the at least one conductive layer further includes a plurality of data lines substantially extending in the second direction. An orthogonal projection of at least one second electrode block on the substrate overlaps with an orthogonal projection of at least one data line on the substrate; and a region where an orthogonal projection of a second electrode block of the at least one second electrode block on the substrate overlaps with an orthogonal projection of a data line of the at least one data line on the substrate is symmetrical with respect to a median line of the second electrode block of the at least one second electrode block in the second direction.

In some embodiments, the plurality of data lines include a plurality of data line groups, and each data line group includes two data lines arranged in parallel. An orthogonal projection of a column of second electrode blocks arranged in the second direction on the substrate at least partially overlaps with each of orthogonal projections of two data lines in a data line group on the substrate; and the two data lines in the data line group are symmetrical with respect to a median line the column of second electrode blocks in the second direction.

In some embodiments, the light-emitting definition layer further has a plurality of second light-transmitting holes; the data line includes third line portions and fourth line portions; an orthogonal projection of a third line portion on the substrate is located within the orthogonal projection of the second electrode block on the substrate; a fourth line portion is located between two adjacent second electrode blocks in the second direction; and an orthogonal projection of each second light-transmitting hole on the substrate is located between orthogonal projections of fourth line portions of two data lines in a single data line group on the substrate.

In some embodiments, in a direction being perpendicular to the substrate and pointing from the substrate to the first electrode layer, the at least one conductive layer includes a first gate conductive layer, a second gate conductive layer, a first source-drain conductive layer, and a second source-drain conductive layer that are arranged in sequence. The first power signal lines are located in the second source-drain conductive layer; and/or the plurality of data lines are located in the first source-drain conductive layer.

In some embodiments, the light-emitting definition layer includes a pixel definition layer, the pixel definition layer is provided therein with a plurality of first openings, and the first light-transmitting hole includes a first opening.

In some embodiments, the light-emitting definition layer further has a plurality of second light-transmitting holes; the pixel definition layer is provided therein with a plurality of second openings; and a second light-transmitting hole includes a second opening.

In some embodiments, the light-emitting definition layer includes a black matrix, the black matrix is provided therein with a plurality of third openings, and the first light-transmitting hole includes a third opening.

In some embodiments, the light-emitting definition layer further has a plurality of second light-transmitting holes; the black matrix is provided therein with a plurality of fourth openings; and a second light-transmitting hole includes a fourth opening.

In some embodiments, the light-emitting definition layer includes a pixel definition layer and a black matrix; the first light-transmitting hole includes a first opening of the pixel definition layer and a third opening of the black matrix; and a shape of an outer contour of the first opening is the same as a shape of an outer contour of the third opening.

In some embodiments, a second light-transmitting hole includes a second opening of the pixel definition layer and a fourth opening of the black matrix, and a shape of an outer contour of the second opening is the same as a shape of an outer contour of the fourth opening.

In some embodiments, the display panel further includes a color filter, and the color filter is disposed on a side of the light-emitting definition layer away from the substrate. The color filter includes a plurality of first filter portions and a plurality of second filter portions; an area of a first filter portion is greater than an area of a second filter portion; an orthogonal projection of a boundary of each first electrode block on the substrate is located within an orthogonal projection of a boundary of a single first filter portion on the substrate; and an orthogonal projection of a boundary of each second electrode block on the substrate is located within an orthogonal projection of a boundary of a single second filter portion on the substrate.

In some embodiments, a shape of an outer contour of the first filter portion is substantially the same as a shape of an outer contour of the first electrode block; and a shape of an outer contour of the second filter portion is substantially the same as a shape of an outer contour of the second electrode block.

In another aspect, a display device is provided. The display device includes the display panel as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is an exploded diagram of a display device, in accordance with some embodiments;

FIG. 3A is a sectional view of a display panel, in accordance with some embodiments;

FIG. 3B is a sectional view of another display panel, in accordance with some embodiments;

FIG. 4 is a structural diagram of a first electrode, in accordance with some embodiments;

FIG. 5 is a structural diagram of another first electrode, in accordance with some embodiments;

FIG. 6 is a top view of a first electrode layer, in accordance with some embodiments;

FIG. 7A is a structural diagram of a first light-transmitting hole in a light-emitting definition layer, in accordance with some embodiments;

FIG. 7B is a structural diagram of a light-emitting definition layer, in accordance with some embodiments;

FIG. 7C is a structural diagram of another light-emitting definition layer, in accordance with some embodiments;

FIG. 7D is a structural diagram of first light-transmitting holes in three rows and three columns and first electrodes in FIG. 7B;

FIG. 7E is a structural diagram of first light-transmitting holes in three rows and three columns and first electrodes in FIG. 7C;

FIG. 8A is a structural diagram of another first light-transmitting hole, in accordance with some embodiments;

FIG. 8B is a structural diagram of yet another light-emitting definition layer, in accordance with some embodiments;

FIG. 8C is a structural diagram of yet another light-emitting definition layer, in accordance with some embodiments;

FIG. 8D is a structural diagram of first light-transmitting holes in three rows and three columns and first electrodes in FIG. 8B;

FIG. 8E is a structural diagram of first light-transmitting holes in three rows and three columns and first electrodes in FIG. 8C;

FIG. 9A is a structural diagram of yet another first light-transmitting hole, in accordance with some embodiments;

FIG. 9B is a structural diagram of yet another light-emitting definition layer, in accordance with some embodiments;

FIG. 9C is a structural diagram of yet another light-emitting definition layer, in accordance with some embodiments;

FIG. 9D is a structural diagram of first light-transmitting holes in three rows and three columns and first electrodes in FIG. 9B;

FIG. 9E is a structural diagram of first light-transmitting holes in three rows and three columns and first electrodes in FIG. 9C;

FIG. 10A is a wiring diagram of first power signal lines and data lines, in accordance with some embodiments;

FIG. 10B is a wiring diagram of first power signal lines and data lines, in accordance with some other embodiments;

FIG. 11 is a top view of first power signal lines, data lines and a first electrode layer, in accordance with some embodiments;

FIG. 12A is a structural diagram of a light-emitting definition layer, in accordance with some embodiments;

FIG. 12B is a structural diagram of another light-emitting definition layer, in accordance with some embodiments;

FIG. 12C is a structural diagram of yet another light-emitting definition layer, in accordance with some embodiments;

FIG. 12D is a structural diagram of yet another light-emitting definition layer, in accordance with some embodiments;

FIG. 12E is a structural diagram of yet another light-emitting definition layer, in accordance with some embodiments;

FIG. 12F is a structural diagram of yet another light-emitting definition layer, in accordance with some embodiments;

FIG. 13 is a top view of a color filter, in accordance with some embodiments; and

FIG. 14 is a top view of a first electrode layer, a pixel definition layer, a black matrix, and a color filter that are stacked, in accordance with some embodiments.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “the plurality of” means two or more unless otherwise specified.

In the description of some embodiments, the terms “connected” and “electrically connected” and their derivatives may be used. For example, the term “connected” may be used in the description of some embodiments to indicate that two or more components are in direct physical or electrical contact with each other. The embodiments disclosed herein are not necessarily limited to the content herein. For example, the term “electrically connected” may be used in the description of some embodiments to indicate that two or more components are in direct physical contact or electrical contact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

In addition, the use of the phrase “based on” or “according to” is meant to be open and inclusive, since a process, step, calculation or other action that is “based on” or “according to” one or more of the stated conditions or values may, in practice, be based on or according to additional conditions or values exceeding those stated.

The term such as “about”, “substantially” or “approximately” as used herein includes a stated value and an average value within an acceptable range of deviation of a particular value determined by a person of ordinary skilled in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

In the embodiments of the present disclosure, transistors used in a pixel circuit may be thin film transistors (TFTs), metal oxide semiconductor (MOS) transistors, or other switching devices with same properties, and the embodiments of the present disclosure are described by taking the thin film transistors as an example.

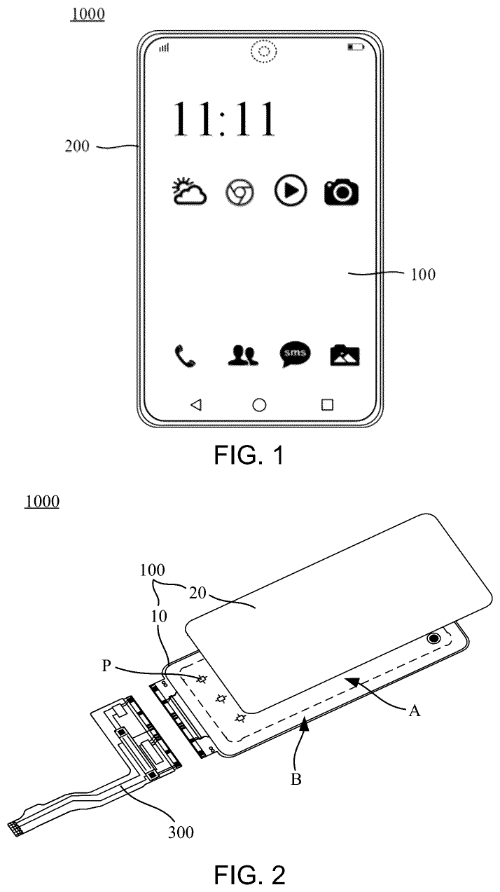

As shown in FIG. 1, some embodiments of the present disclosure provide a display device 1000. The display device 1000 may be any device that displays an image whether in motion (e.g., a video) or stationary (e.g., a still image), and whether textual or graphical. For example, the display device 1000 may be any product or component having a display function, such as a television, a notebook computer, a tablet computer, a mobile phone, a personal digital assistant (PDA), a navigator, a wearable device, or a virtual reality (VR) device.

In some embodiments, referring to FIG. 1, the display device 1000 includes a display panel 100.

For example, as shown in FIG. 1, the display device 1000 may further include a housing 200, a circuit board 300 (see FIG. 2), and other electronic accessories. The display panel 100 and the circuit board 300 (see FIG. 2) may be arranged inside the housing 200.

A type of the display panel 100 varies, which may be set according to actual needs.

For example, the display panel 100 may be an organic light-emitting diode (OLED) display panel, a quantum dot light-emitting diode (QLED) display panel, or the like, which is not specifically limited in the embodiments of the present disclosure.

Some embodiments of the present disclosure are schematically described below by considering an example in which the display panel 100 is the OLED display panel.

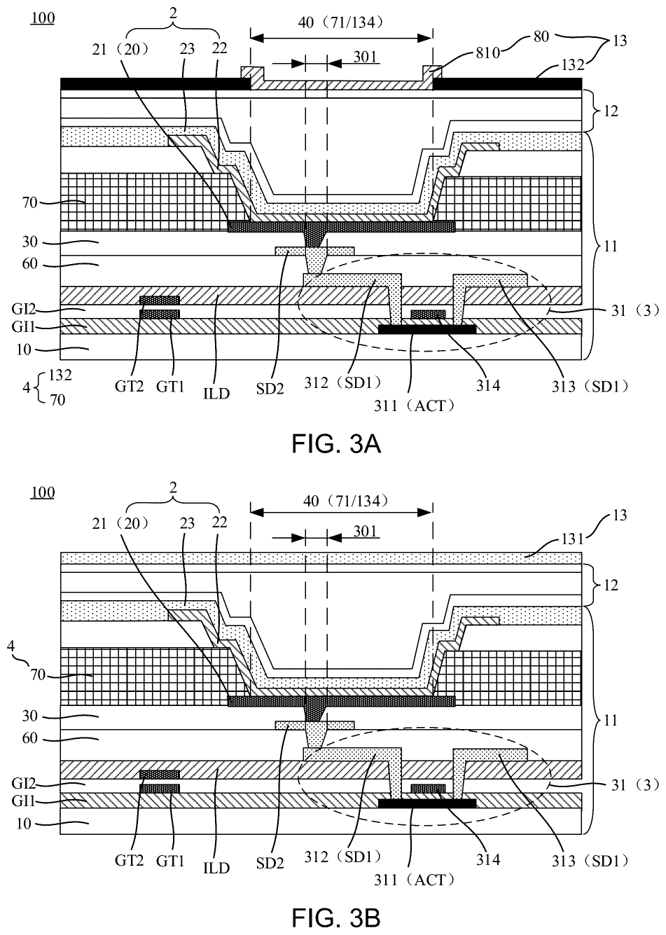

In some embodiments, referring to FIG. 3A, the display panel 100 includes a display substrate 11 and an encapsulation layer 12 for encapsulating the display substrate 11.

As shown in FIGS. 2 and 3A, the display substrate 11 has a light-exit side and a non-light-exit side that are arranged opposite to each other; and the encapsulation layer 12 is disposed on the light-exit side of the display substrate 11, that is, an upper side in FIG. 3A. Here, the encapsulation layer 12 may be an encapsulation film or an encapsulation substrate.

Referring to FIG. 2, the display panel 100 has a display region AA and a peripheral region S disposed on at least one side of the display region AA. FIG. 2 illustrates an example in which the peripheral region B is disposed around the display region A.

The display region A is a region for displaying images, and is configured for arranging a plurality of sub-pixels P. The peripheral region B is a region where no image is displayed, and the peripheral region B is configured for arranging a display driver circuit (such as a gate driver circuit and a source driver circuit).

For example, referring to FIGS. 2 and 3A, the display panel 100 includes a substrate 10 and a plurality of sub-pixels P that are disposed on a side of the substrate 10 and located in the display region A.

A type of the substrate 10 varies, which may be set according to actual needs.

For example, the substrate 10 is a rigid substrate. For example, the rigid substrate is a glass substrate or a polymethyl methacrylate (PMMA) substrate.

For example, the substrate 10 is a flexible substrate. For example, the flexible substrate is a polyethylene terephthalate (PET) substrate, a polyethylene naphthalate (PEN) substrate, or a polyimide (PI) substrate.

Referring to FIG. 3A, the plurality of sub-pixels P may include first sub-pixels that emit light of a first color, second sub-pixels that emit light of a second color, and third sub-pixels that emit light of a third color.

The first, second and third colors are three primary colors. For example, the first color is red, the second color is blue, and the third color is green. The embodiments of the present disclosure will be illustrated below by taking an example in which the first color is blue, the second color is green and the third color is red.

It should be understood that the human eye has different sensitivity levels to red light, green light and blue light. That is, the human eye is more sensitive to green light than to red light, and is more sensitive to red light than to blue light.

On this basis, an area of an effective light-emitting region of the first sub-pixel is greater than an area of an effective light-emitting region of the third sub-pixel; and the area of the effective light-emitting region of the first sub-pixel is greater than an area of an effective light-emitting region of the second sub-pixel. Here, as for the description of the effective light-emitting region, reference may be made to the following description.

In addition, each sub-pixel P includes a light-emitting device 2 and a pixel circuit 3 that are disposed on the substrate 10. The pixel circuit 3 includes a plurality of TFTs 31.

As shown in FIG. 3A, the TFT 31 includes an active layer 311, a source 312, a drain 313 and a gate 314. The source 312 and the drain 313 are in contact with the active layer 311.

It should be noted that the source 312 and the drain 313 may be interchanged. That is, 312 in FIG. 3A indicates the drain, and 313 in FIG. 3A indicates the source.

As shown in FIG. 3A, the light-emitting device 2 includes a first electrode 21, a light-emitting functional layer 22, and a second electrode 23. The first electrode 21 is electrically connected to a source 312 or drain 313 of a TFT 31, serving as a driving transistor, among the plurality of TFTs 31. FIG. 3A illustrates an example in which the first electrode 21 is electrically connected to the source 312 of the TFT 31.

It should be noted that the first electrode 21 is an anode of the light-emitting device 2, and the second electrode 23 is a cathode of the light-emitting device 2; alternatively, the first electrode 21 is the cathode of the light-emitting device 2, and the second electrode 23 is the anode of the light-emitting device 2.

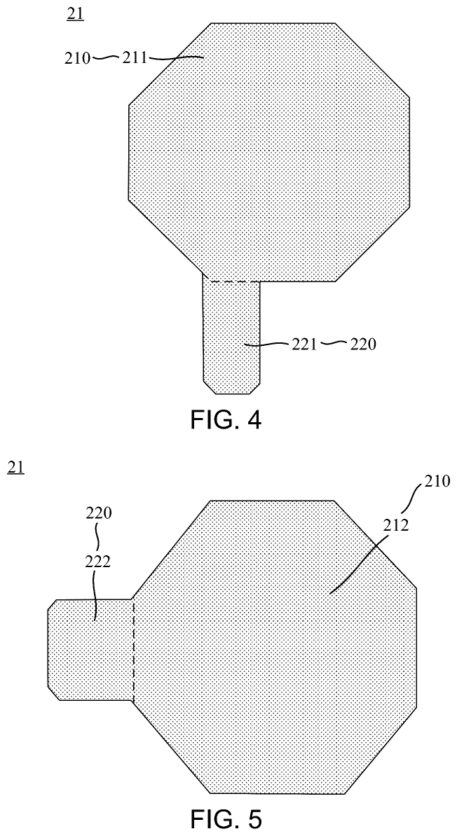

In some embodiments, referring to FIGS. 4 and 5, the first electrode 21 includes an electrode block 210 and a connection strip 220.

As shown in FIGS. 3A and 4, the electrode block 210 is configured to be in contact with the light-emitting functional layer 22, so as to form a light-emitting region. That is, an orthogonal projection of the light-emitting region on the substrate 10 is located within an orthogonal projection of the electrode block 210 on the substrate 10.

As shown in FIGS. 3A and 4, the connection strip 220 is configured to be electrically connected to the pixel circuit 3. That is, the connection strip 220 is electrically connected to the source 312 or the drain 313 of the TFT 31.

It should be noted that the first electrode 21 is located in a first electrode layer 20. That is, the first electrode layer 20 includes a plurality of electrode blocks 210 and a plurality of connection strips 220. The plurality of electrode blocks 210 and the plurality of connection strips 220 are formed by patterning the first electrode layer 20.

In some embodiments, referring to FIGS. 2 and 3A, the second electrode 23 is a continuous whole-layer pattern and covers the entire display region A.

In some embodiments, referring to FIG. 3A, the light-emitting functional layer 22 only includes a light-emitting layer. In some other embodiments, the light-emitting functional layer 22 includes the light-emitting layer, and further includes at least one of an electron transport layer (ETL), an electron injection layer (EIL), a hole transport layer (HTL) or a hole injection layer (HIL).

In some embodiments, as shown in FIG. 3A, the display panel 100 further includes a pixel definition layer 70, and the pixel definition layer 70 is disposed on a side of the first electrode 21 away from the substrate 10. The pixel definition layer 70 has a plurality of first openings 71. The light-emitting device 2 corresponds to a first opening 71. That is, the light-emitting functional layer 22 of the light-emitting device 2 is in electrical contact with the electrode block 210 of the first electrode 21 in the first opening 71.

It should be noted that, in order to reduce the difficulty of processing, an area of the first electrode 21 is greater than an area of the first opening 71 of the pixel definition layer 70, so that the entire first opening 71 of the pixel definition layer 70 forms a light-emitting region. That is, an overlapping region of the first electrode 21, the second electrode 23 and the light-emitting functional layer 22 form a light-emitting region.

Here, when there is no other light-shielding film layer blocking the first openings 71 of the pixel definition layer 70, the effective light-emitting region is a region defined by the first opening 71. That is, the light-emitting region is the effective light-emitting region.

In some embodiments, as shown in FIGS. 3A and 3B, the display panel 100 includes an anti-reflective film 13, and the anti-reflective film 13 is configured to reduce a reflection intensity of external ambient light on the display panel 100.

In some examples, referring to FIG. 3B, the anti-reflective film 13 includes a polarizer 131, and the polarizer 131 is disposed on a side of the encapsulation layer 12 away from the substrate 10.

In some other examples, referring to FIG. 3A, the anti-reflective film 13 includes a black matrix 132 and a color filter 80. The black matrix 132 is used to separate light emitted from different sub-pixels P, and has a function of reducing the reflected light generated after the external ambient light enters the interior of the display panel 100. The color film 80 may filter out most wavelength bands of the external ambient light, thereby reducing the reflection intensity of the external ambient light on the display panel 100.

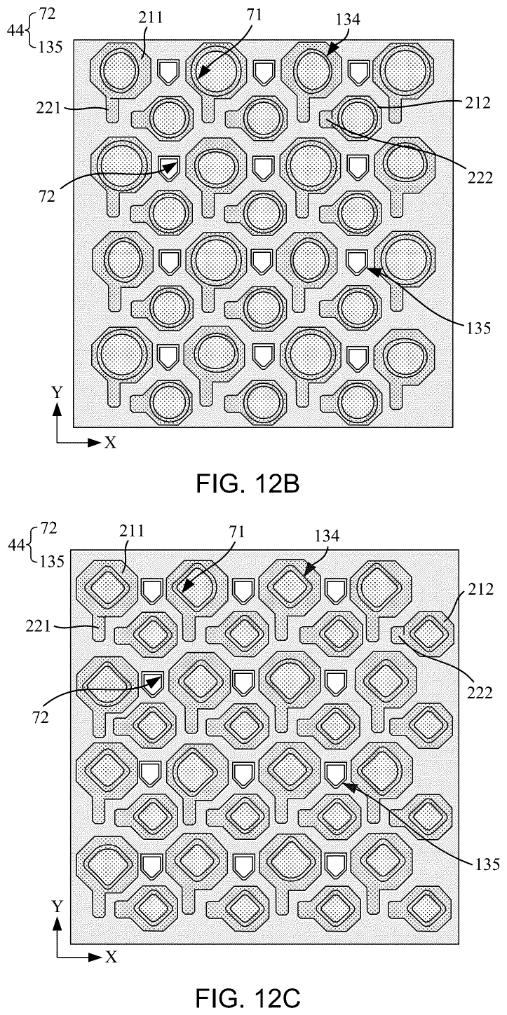

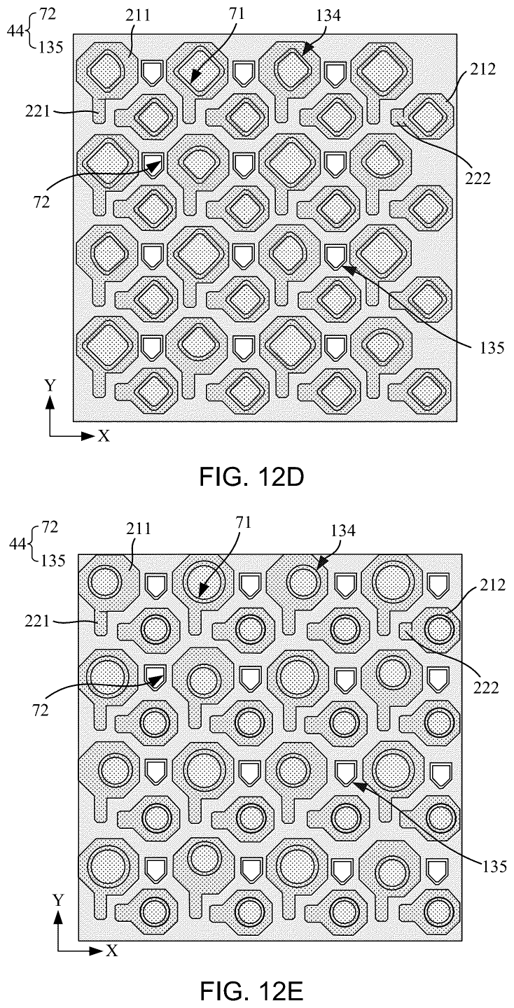

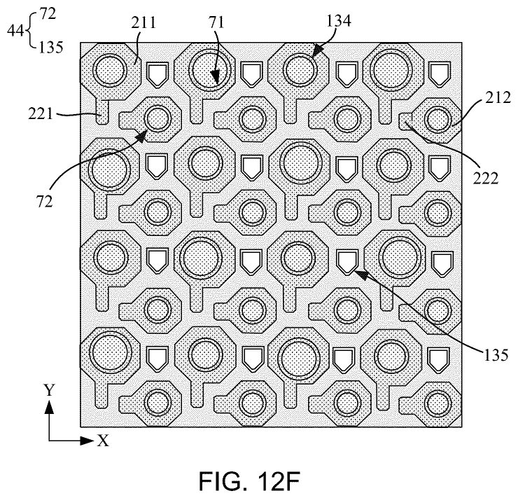

Referring to FIGS. 3A and 12A, the black matrix 132 is disposed on a side of the pixel definition layer 70 away from the substrate 10. The black matrix 132 has a plurality of third openings 134, and a single third opening 134 exposes at least part of the first opening 71.

It should be noted that in the case where the display panel 100 includes the black matrix 132, the effective light-emitting region is a region where the first opening 71 and the third opening 134 overlap.

Here, referring to FIGS. 3A and 12A, a shape of an outer contour of the third opening 134 of the black matrix 132 may be the same as a shape of an outer contour of the first opening 71 of the pixel definition layer 70.

In addition, a size of the third opening 134 of the black matrix 132 may be greater than a size of the first opening 71 of the pixel definition layer 70, or may be less than the size of the first opening 71 of the pixel definition layer 70.

For example, as shown in FIG. 12A, the size of the third opening 134 of the black matrix 132 is greater than the size of the first opening 71 of the pixel definition layer 70; and a distance between a boundary of an orthogonal projection of the third opening 134 on the substrate 10 (see FIG. 3A) and a boundary of an orthogonal projection of the first opening 71 on the substrate 10 (see FIG. 3A) is in a range of 2 μm to 6 μm.

In the related art, the shape and area of the electrode block of the first electrode included in the first electrode layer are adjusted based on the area of the effective light-emitting region. That is, the shape and area of the electrode block of the first electrode are adaptively adjusted based on the first opening of the pixel definition layer or the third opening of the black matrix. In this case, since the areas of the effective light-emitting regions of sub-pixels of different colors are different, the areas of the electrode blocks of the first electrodes are different for the sub-pixels of different colors, causing high manufacturing costs.

In addition, in different OLED display devices, the shapes of the first openings of the pixel definition layers and the third openings of the black matrices are not unique. In this case, in the process of manufacturing OLED display devices corresponding to different pixel definition layers or black matrices, the first electrode layers have poor versatility, resulting in high manufacturing costs.

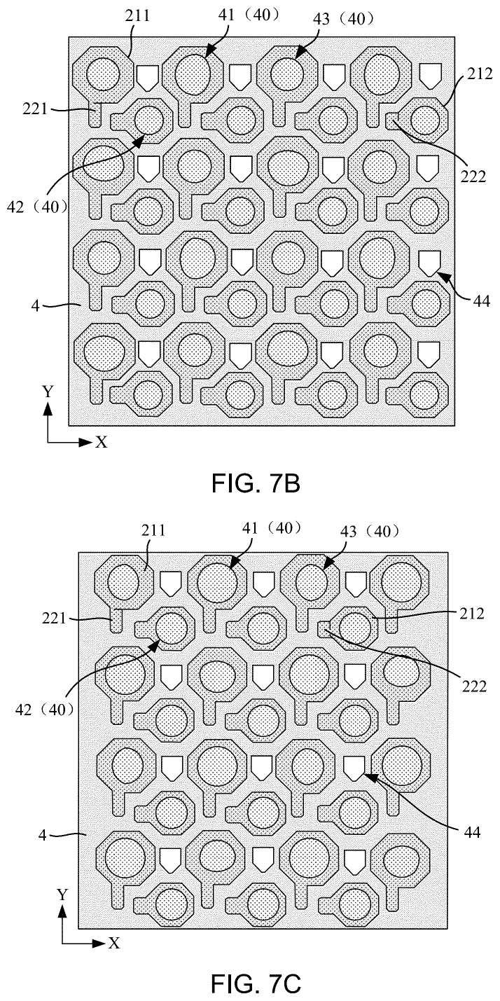

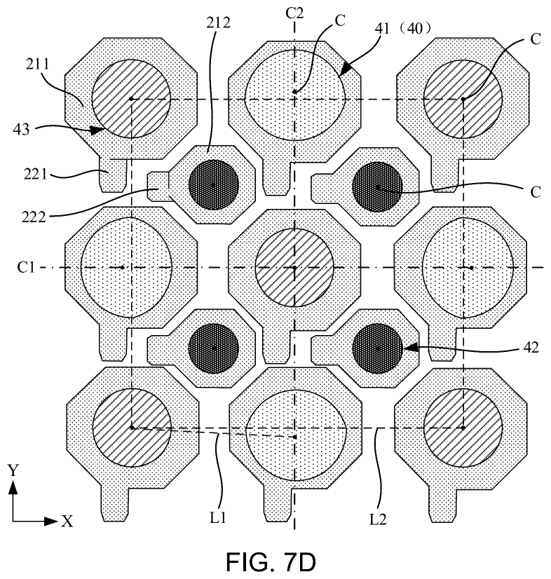

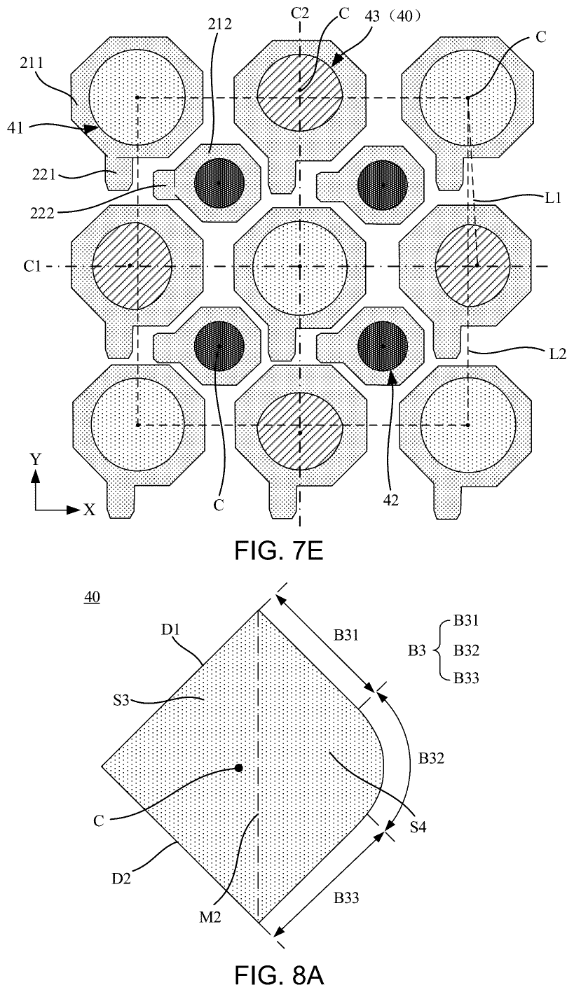

In light of this, the display panel 100 provided in some embodiments of the present disclosure, referring to FIGS. 3A and 7B, includes a light-emitting definition layer 4. The light-emitting definition layer 4 has a plurality of first light-transmitting holes 40, and orthogonal projections of the first light-transmitting holes 40 on the substrate 10 are effective light-emitting regions.

In some examples, the light-emitting definition layer 4 includes the pixel definition layer 70, the first light-transmitting hole 40 includes a first opening 71 in the pixel definition layer 70, and the effective light-emitting region is a region defined by the first opening 71.

In some other examples, the light-emitting definition layer 4 includes the black matrix 132, the first light-transmitting hole 40 includes a third opening 134, and the effective light-emitting region is a region defined by the third opening 134.

In yet some other examples, the light-emitting definition layer 4 includes the pixel definition layer 70 and the black matrix 132. The first light-transmitting hole 40 includes a first opening 71 and a third opening 134, and the effective light-emitting region is a region where the first opening 71 and the third opening 134 overlap.

FIGS. 7A to 9E illustrate examples where the light-emitting definition layer 4 includes the pixel definition layer 70 or the black matrix 132. FIGS. 12A to 12F illustrate examples where the light-emitting definition layer 4 includes the pixel definition layer 70 and the black matrix 132.

Referring to FIGS. 4 and 5, the plurality of electrode blocks 210 of the plurality of first electrodes 21 include a plurality of first electrode blocks 211 and a plurality of second electrode blocks 212.

As shown in FIG. 7B, at least a part of each first electrode block 211 is exposed by a first light-transmitting hole 40, and at least a part of each second electrode block 212 is exposed by a first light-transmitting hole 40, so as to form effective light-emitting regions.

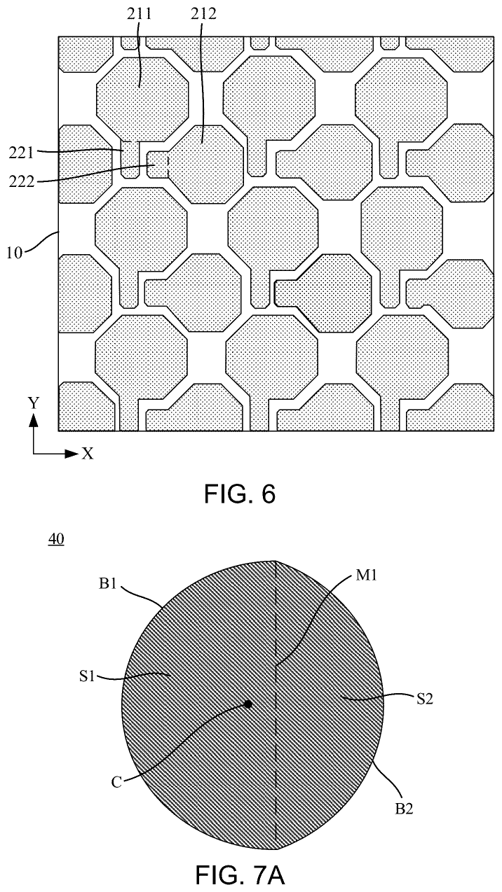

Referring to FIG. 6, the plurality of first electrode blocks 211 are arranged in an array of rows and columns, each row includes a plurality of first electrode blocks 211 arranged in a first direction X, and each column includes a plurality of first electrode blocks 211 arranged in a second direction Y, the first direction X being substantially perpendicular to the second direction Y. Each second electrode block 212 is located between four adjacent first electrode blocks 211 arranged in two rows and two columns.

Here, an area of the first electrode block 211 is greater than an area of the second electrode block 212, so that the first electrode block 211 matches the sub-pixel P with a larger area of the effective light-emitting region.

For example, referring to FIG. 7B, the first electrode blocks 211 match first sub-pixels and third sub-pixels. That is, among all the first electrode blocks 211, some first electrode blocks 211 serve as portions of first electrodes 21 (see FIG. 3A) of light-emitting device 2 (see FIG. 3A) of the first sub-pixels for forming effective light-emitting regions, and some other first electrode blocks 211 serve as portions of first electrodes 21 (see FIG. 3A) of light-emitting device 2 (see FIG. 3A) of the third sub-pixels for forming effective light-emitting regions. The second electrode blocks 212 serve as portions of first electrodes 21 (see FIG. 3A) of light-emitting device 2 (see FIG. 3A) of the second sub-pixels for forming effective light-emitting regions.

It can be seen from the above that, the first electrode layer 20 provided in the embodiments of the present disclosure includes first electrode blocks 211 with larger areas and second electrode blocks 212 with smaller areas. The first electrode blocks 211 may be adapted to the sub-pixels P (e.g., the first sub-pixels) with largest areas of the effective light-emitting regions, and the second electrode blocks 212 may be adapted to the sub-pixels P (e.g., the second sub-pixels) with the smallest areas of the effective light-emitting regions.

In this case, since the area of the first electrode block 211 is greater than the area of the effective light-emitting region of the remaining sub-pixel P, the effective light-emitting regions of the remaining sub-pixels P (e.g., the third sub-pixels) may be formed on the first electrode blocks 211. That is to say, the first electrode layer 20 provided in the embodiments of the present disclosure only includes two types of electrode blocks 210, which may be adapted to at least three types of sub-pixels P. In this way, it may be possible to reduce the process difficulty of patterning of the first electrode layer 20 and in turn reduce the costs of fabricating the plurality of first electrodes 21.

It should be understood that, since the shapes of the first openings 71 of the pixel definition layer 70 and the third openings 134 of the black matrix 132 are not unique, the shapes of the first light-transmitting holes 40 of the light-emitting definition layer 4 are also not unique. Here, the shapes and areas of the first electrode blocks 211 and the second electrode blocks 212 may be adjusted accordingly to adapt to different types of light-emitting definition layers 4, thereby reducing the costs of manufacturing the display devices 1000 corresponding to different light-emitting definition layers 4.

For example, referring to FIGS. 4 and 5, each of an outer contour of the first electrode block 211 and an outer contour of the second electrode block 212 is substantially in a shape of a polygon.

For example, as shown in FIGS. 4 and 5, orthogonal projections of the first electrode block 211 and the second electrode block 212 on the substrate 10 are each substantially in a shape of a regular octagon. Of course, the orthogonal projections of the first electrode block 211 and the second electrode block 212 on the substrate 10 may also be in a shape of a regular hexagon, a regular decagon, a regular dodecagon, etc., which will not be specifically limited in the embodiments of the present disclosure.

As shown in FIG. 6, borders of any adjacent first electrode block 211 and second electrode block 212 are opposite and substantially parallel to each other, and a distance between adjacent first electrode block 211 and second electrode block 212 is substantially equal to a first preset value.

Here, the first preset value is a process limit value at which the first electrode block 211 and the second electrode block 212 are disconnected. That is, the first preset value may be determined according to the process accuracy, with the basis of enabling the disconnection between the first electrode block 211 and the second electrode block 212 in the same layer. For example, the first preset value is in a range of 3.5 μm to 6.5 μm. For example, the first preset value is any one of 3.5 μm, 4 μm, 4.5 μm, 5 μm, 5.5 μm, 6 μm, and 6.5 μm.

In this case, on a plane determined by the first direction X and the second direction Y of the substrate 10, an area utilization ratio of the first electrode blocks 211 and the second electrode blocks 212 is high, so that the areas of the first electrode blocks 211 and the second electrode blocks 212 are set larger. Therefore, the first light-transmitting holes 40 with smallest areas of various light-emitting definition layers 4 may be formed on the first electrode blocks 211, and other first light-transmitting holes 40 with larger areas may be formed on the second electrode blocks 212, which improves the universality of the first electrode layer 20. As a result, the display devices 1000 corresponding to different light-emitting definition layers 4 may use the above-mentioned first electrode layer 20, to reduce the costs of manufacturing various display devices 1000 corresponding to different light-emitting definition layers 4.

In some embodiments, referring to FIGS. 6 and 7A, at least part of a boundary of at least one first light-transmitting hole 40 of the light-emitting definition layer 4 is curved. In this way, when the external ambient light incident on the first electrode block 211 or the second electrode block 212 and reflected to the outside through the first light-transmitting hole 40 of the light-emitting definition layer 4 causes diffraction, the diffraction caused by the external ambient light may be evenly distributed at the curved boundary of the first light-transmitting hole(s) 40, thereby mitigating color separation caused by the external ambient light.

In addition, in the case where the plurality of sub-pixels P includes the first sub-pixels, the second sub-pixels and the third sub-pixels, as shown in FIG. 7B, the plurality of first light-transmitting holes 40 may include a plurality of first light-transmitting sub-holes 41, a plurality of second light-transmitting sub-holes 42, and a plurality of third light-transmitting sub-holes 43. The first light-transmitting sub-hole 41 and the third light-transmitting sub-hole 43 each expose at least part of a first electrode block 211, and the second light-transmitting sub-hole 42 exposes at least a part of a second electrode block 212. A plurality of first light-transmitting sub-holes 41 and a plurality of third light-transmitting sub-holes 43 are arranged alternately in the first direction X. A plurality of first light-transmitting sub-holes 41 and a plurality of third light-transmitting sub-holes 43 are arranged alternately in the second direction Y.

At least part of a boundary of at least one of the first light-transmitting sub-hole 41, the second light-transmitting sub-hole 42 and the third light-transmitting sub-hole 43 is curved, so that the same sub-pixels P (see FIG. 2) have the same distribution of light-emitting centers C (see FIG. 7A), which makes the brightness distribution of the display panel 100 more uniform and improves the display effect.

It should be noted that an area of the first light-transmitting sub-hole 41 is greater than an area of the third light-transmitting sub-hole 43; the area of the third light-transmitting sub-hole 43 is greater than an area of the second light-transmitting sub-hole 42. For example, the first light-transmitting sub-hole 41 corresponds to the first sub-pixel, the second light-transmitting sub-hole 42 corresponds to the second sub-pixel, and the third light-transmitting sub-hole 43 corresponds to the third sub-pixel.

In some embodiments, as shown in FIG. 7A, an outer contour of at least one first light-transmitting hole 40 includes a first curved border B1 and a second curved border B2. Two ends of the first curved border B1 are respectively connected to two ends of the second curved border B2. Two connection points of the first curved border B1 and the second curved border B2 are a first connection point and a second connection point.

A line connecting the first connection point and the second connection point is a first line segment M1. A length of the first line segment M1 is the maximum dimension of the first light-transmitting hole 40. The first line segment M1 divides the first light-transmitting hole 40 into a first sub-portion S1 including the first curved border B1 and a second sub-portion S2 including the second curved border B2. An area of the first sub-portion S1 is greater than an area of the second sub-portion S2. In this case, the light-emitting center C of the first light-transmitting hole 40 is located in the first sub-portion S1.

For example, as shown in FIG. 7A, the first curved border B1 and the first line segment M1 constitute a semicircle, and the second curved border B2 and the first line segment M1 constitute a semiellipse. In this case, an area of the semicircle is greater than an area of the semiellipse, and the light-transmitting center C is located on a side of a center of the semicircle away from the semiellipse, that is, located within the semicircle.

Here, in the case where the plurality of first light-transmitting holes 40 includes the plurality of first light-transmitting sub-holes 41, the plurality of second light-transmitting sub-holes 42 and the plurality of third light-transmitting sub-holes 43, an outer contour of the first light-transmitting sub-hole 41 and/or an outer contour of the third light-transmitting sub-hole 43 includes the first curved border B1 and the second curved border B2, and an outer contour of the second light-transmitting sub-hole 42 is substantially in a shape of a circle or an ellipse.

It will be noted that the term “substantially in a shape of a circle or an ellipse” herein means in a shape of a circle or an ellipse as a whole, but is not limited to a standard circle or ellipse. That is, “circle or ellipse” herein includes not only a substantial circle or ellipse but also a shape similar to a circle or ellipse in consideration of process conditions. For example, a part of a circle or ellipse is a straight line.

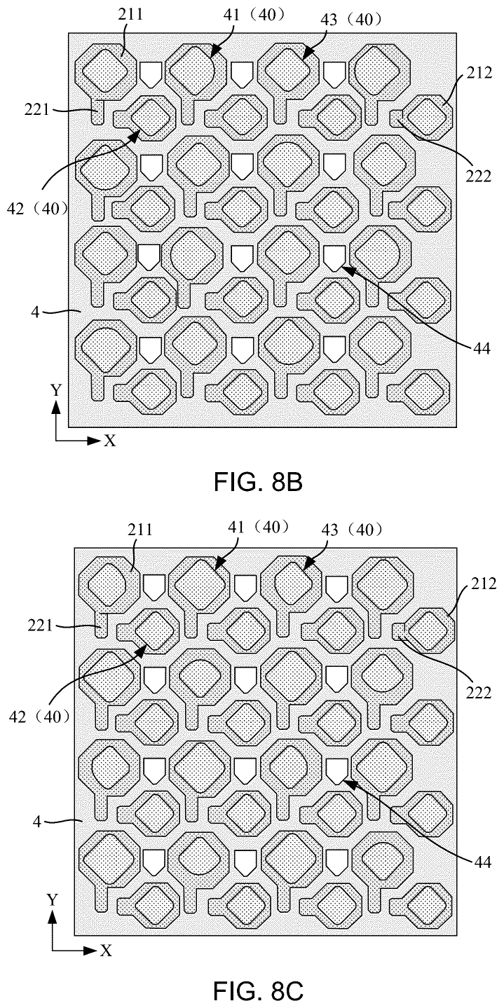

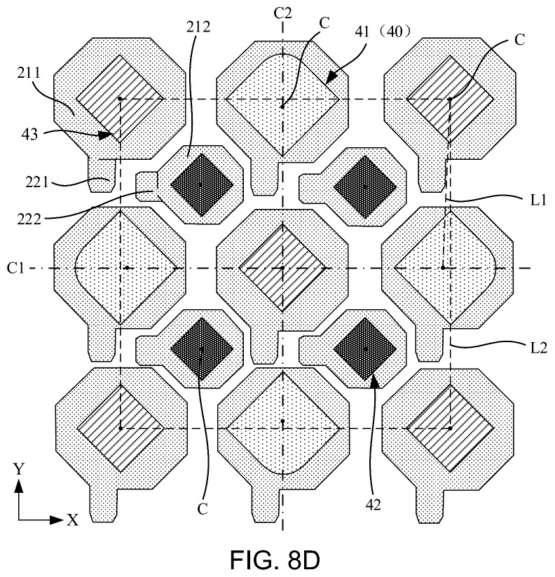

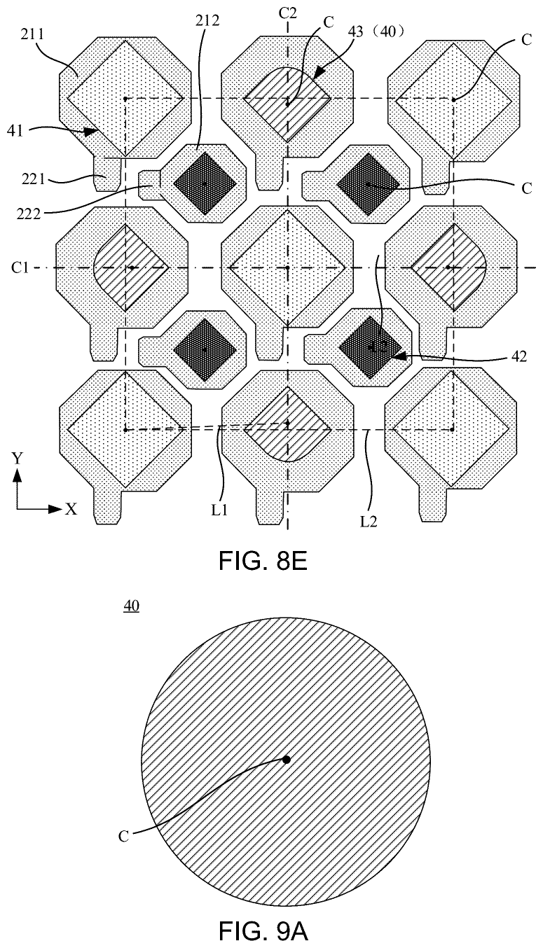

In some other embodiments, as shown in FIG. 8A, an outer contour of at least one first light-transmitting hole 40 includes a first straight border D1, a second straight border D2, and a third curved border B3. The first straight border D1 and the second straight border D2 are connected to form a polyline-shaped border, two ends of the third curved border B3 are respectively connected to two ends of the polyline-shaped border, and two connection points for the two ends of the third curved border B3 connecting the polyline-shaped border are a third connection point and a fourth connection point.

A line connecting the third connection point and the fourth connection point is a second line segment M2. A length of the second line segment M2 is the maximum dimension of the first light-transmitting hole 40. The second line segment M2 divides the first light-transmitting hole 40 into a third sub-portion S3 including the first straight border D1 and the second straight border D2 and a fourth sub-portion S4 including the third curved border B3. An area of the third sub-portion S3 is greater than an area of the fourth sub-portion S4. In this case, the light-emitting center C of the first light-transmitting hole 40 is located in the third sub-portion S3.

For example, as shown in FIG. 8A, the third curved border B3 includes a first straight sub-line segment B31, a first curved sub-line segment B32 and a second straight sub-line segment B33 connected in sequence. The first straight sub-line segment B31 is connected to the first straight border D1, and the second straight sub-line segment B33 is connected to the second straight border D2. The first straight sub-line segment B31 is substantially parallel to the second straight border D2, and the second straight sub-line segment B33 is substantially parallel to the first straight border D1. In this case, since the length of the second line segment M2 is the maximum dimension of the first light-transmitting hole 40, the area of the third sub-portion S3 is greater than the area of the fourth sub-portion S4, and the light-emitting center C is located in the third sub-portion S3.

Here, in the case where the plurality of first light-transmitting holes 40 includes the plurality of first light-transmitting sub-holes 41, the plurality of second light-transmitting sub-holes 42 and the plurality of third light-transmitting sub-holes 43, an outer contour of the first light-transmitting sub-hole 41 and/or an outer contour of the third light-transmitting sub-hole 43 includes the first straight border D1, the second straight border D2 and the third curved border B3, and an outer contour of the second light-transmitting sub-hole 42 is substantially in a shape of a rhombus.

It will be noted that the term “substantially in a shape of a rhombus” herein means in a shape of a rhombus as a whole, but is not limited to a standard rhombus. That is, “rhombus” herein includes not only a substantial rhombus but also a shape similar to a rhombus in consideration of process conditions. For example, corners of a rhombus are curved, that is, the corners are smooth.

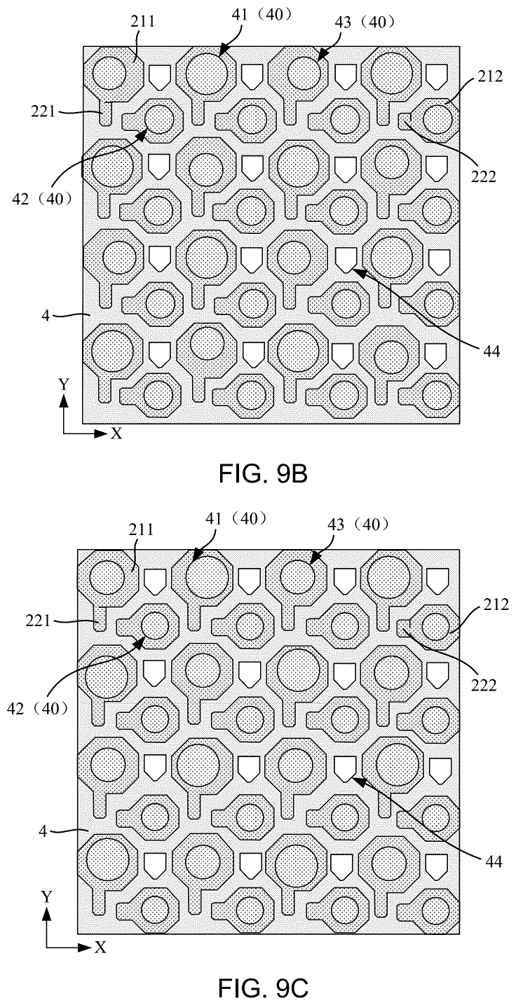

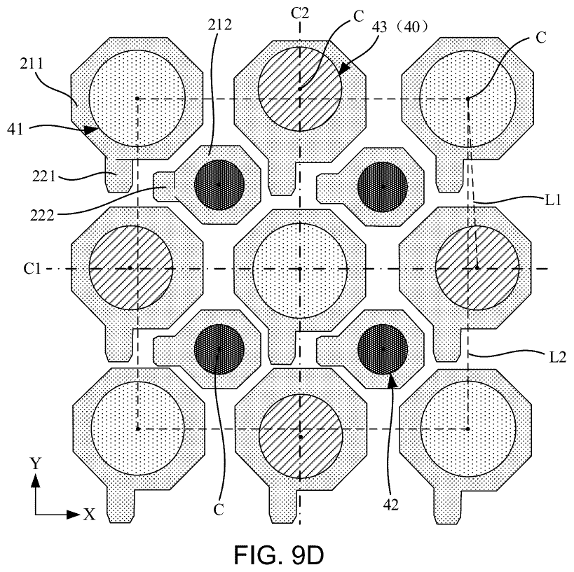

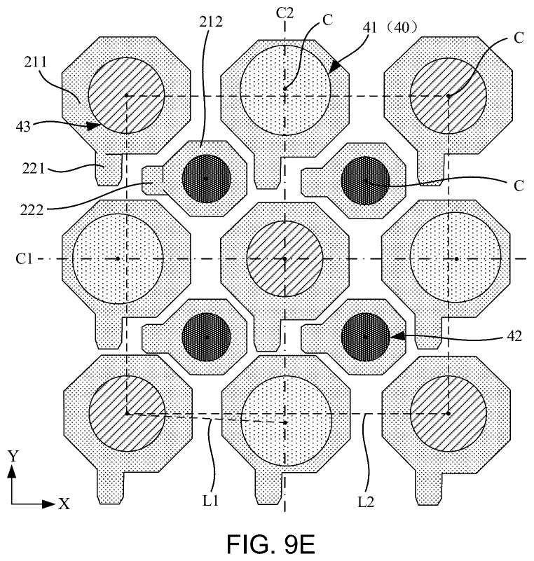

In yet some other embodiments, as shown in FIG. 9A, an outer contour of at least one first light-transmitting hole 40 is substantially in a shape of a circle or an ellipse. In this case, a light-emitting center C of the first light-transmitting hole 40 is a center of the circle or a center of the ellipse. FIG. 9A illustrates an example where the outer contour of the first light-transmitting hole is substantially in a shape of a circle.

Here, in the case where the plurality of first light-transmitting holes 40 includes the plurality of first light-transmitting sub-holes 41, the plurality of second light-transmitting sub-holes 42 and the plurality of third light-transmitting sub-holes 43, each of outer contours of the first light-transmitting sub-hole 41, the second light-transmitting sub-hole 42 and the third light-transmitting sub-hole 43 is substantially in a shape of a circle or an ellipse.

It can be understood that positions of light-emitting centers C of different sub-pixels P (see FIG. 2) in the display panel 100 may also be flexibly adjusted, so that an actual brightness center of a pixel unit composed of multiple sub-pixels P is adjusted. Therefore, the distribution of actual brightness centers of pixel units in the entire display panel 100 is more even.

In some embodiments, referring to FIGS. 7D, 8D and 9D, a line connecting centers of adjacent first light-transmitting sub-hole 41 and third light-transmitting sub-hole 43 is a first connection line L1, and a line connecting centers of two first electrode blocks 211 corresponding to the adjacent first light-transmitting sub-hole 41 and third light-transmitting sub-hole 43 is a second connection line L2. There is at least one first connection line L1 that is not parallel to a corresponding second connection line L2.

In this way, the light-emitting centers C of the sub-pixels P (see FIG. 2) may be adjusted, so that the actual brightness center of the pixel unit composed of multiple sub-pixels P is adjusted. Therefore, the distribution of actual brightness centers of pixel units in the entire display panel 100 is more even.

On this basis, referring to FIGS. 7D, 8D and 9D, among nine first light-transmitting holes 40 corresponding to nine first electrode blocks 211 that are adjacently arranged in three rows and three columns, a line connecting centers of four first light-transmitting holes 40 located at four corners enclose a virtual quadrilateral. The virtual quadrilateral has a first median line C1 extending in the first direction X and a second median line C2 extending in the second direction Y. Here, both the first median line C1 and the second median line C2 pass through a light-emitting center C of a first light-transmitting hole 40 located in the center of the nine first light-transmitting holes 40.

The nine first light-transmitting holes 40 are symmetrical with respect to the first median line C1 and/or the second median line C2, so as to avoid the color separation of the display panel 100 caused by the deviation of the light-emitting centers C of multiple sub-pixels P in a single pixel unit. Thus, the display effect is improved.

In some examples, referring to FIGS. 7D, 8D and 9D, the virtual quadrilateral is substantially a rectangle; and among four sides of the rectangle, two sides are substantially parallel to the first direction X, and the other two sides are substantially parallel to the second direction Y.

In this case, the nine first light-transmitting holes 40 are symmetrical with respect to the first median line C1, and the nine first light-transmitting holes 40 are also symmetrical with respect to the second median line C2. The nine first light-transmitting holes 40 are centrally symmetrically distributed about the center of the virtual quadrilateral, so as to avoid the color separation of the display panel 100 caused by the deviation of the light-emitting centers C of multiple sub-pixels P in a single pixel unit. Thus, the display effect is improved.

In some other examples, the virtual quadrilateral is substantially an isosceles trapezoid, and top and bottom sides of the isosceles trapezoid are substantially parallel to the first direction X.

In this case, the nine first light-transmitting holes 40 are symmetrical with respect to the second median line C2, and two first light-transmitting holes 40 that are respectively located in the middle of the top side of the isosceles trapezoid and the middle of the bottom side of the isosceles trapezoid among the nine first light-transmitting holes 40 are also symmetrical with respect to the first median line C1, so as to avoid the color separation of the display panel 100 caused by the deviation of the light-emitting centers C of multiple sub-pixels P in a single pixel unit. Thus, the display effect is improved.

In yet some other examples, the virtual quadrilateral is substantially an isosceles trapezoid, and top and bottom sides of the isosceles trapezoid are substantially parallel to the second direction Y.

In this case, the nine first light-transmitting holes 40 are symmetrical with respect to the first median line C1, and two first light-transmitting holes 40 that are respectively located in the middle of the top side of the isosceles trapezoid and the middle of the bottom side of the isosceles trapezoid among the nine first light-transmitting holes 40 are also symmetrical with respect to the second median line C2, so as to avoid the color separation of the display panel 100 caused by the deviation of the light-emitting centers C of multiple sub-pixels P in a single pixel unit. Thus, the display effect is improved.

Some embodiments of the present disclosure will be schematically described below by taking an example in which the virtual quadrilateral is substantially a rectangle.

In some embodiments, referring to FIGS. 7D and 7E, one type of light-transmitting sub-holes of first light-transmitting sub-holes 41 and third light-transmitting sub-holes 43 are located at the center and four corners of the virtual quadrilateral, the other type of light-transmitting sub-holes of first light-transmitting sub-holes 41 and third light-transmitting sub-holes 43 are located at the four sides of the virtual quadrilateral. The first light-transmitting holes 40 located at the center and four corners of the virtual quadrilateral are set light-transmitting holes, and the first light-transmitting holes 40 located at the four sides of the virtual quadrilateral are non-set light-transmitting holes.

It should be noted that in some embodiments, as shown in FIG. 7E, the set light-transmitting holes are first light-transmitting sub-holes 41, and the non-set light-transmitting holes are third light-transmitting sub-holes 43. In some other embodiments, as shown in FIG. 7D, the set light-transmitting holes are third light-transmitting sub-holes 43, and the non-set light-transmitting holes are first light-transmitting sub-holes 41, which will be described in the present disclosure below in combination with specific embodiments, and details will not be provided here.

As shown in FIGS. 7D and 7E, the light-emitting center C of the set light-transmitting hole substantially coincides with the center of the corresponding first electrode block 211, and the light-emitting center C of the second light-transmitting sub-hole 42 substantially coincides with the center of the corresponding second electrode block 212.

In this case, a plurality of set light-transmitting holes and a plurality of second light-transmitting sub-holes 42 are symmetrical with respect to the first median line C1 and/or the second median line C2.

On this basis, among two non-set light-transmitting holes opposite to each other in the first direction X, a center of one non-set light-transmitting hole is located on a first side of a center of a corresponding first electrode block 211, and a center of another non-set light-transmitting hole is located on a second side of a center of a corresponding first electrode block 211.

In this case, the two non-set light-transmitting holes opposite to each other in the first direction X are symmetrical with respect to the second median line C2.

In addition, among two non-set light-transmitting holes opposite to each other in the second direction Y, a center of one non-set light-transmitting hole is located on a third side of a center of a corresponding first electrode block 211, and a center of another non-set light-transmitting hole is located on a fourth side of a center of a corresponding first electrode block 211.

In this case, the two non-set light-transmitting holes opposite to each other in the second direction Y are symmetrical with respect to the first median line C1.

It should be noted that, a first side and a second side are two opposite sides of a center of a first electrode block 211, and a third side and a fourth side are other two opposite sides of the center of the first electrode block 211. For example, the first side, second side, third side and fourth side are four sides of the center of the first electrode block 211 in the first direction X and second direction Y.

For example, as shown in FIGS. 7B and 7D, the first light-transmitting sub-hole 41 is the non-set light-transmitting hole, and the third light-transmitting sub-hole 43 is the set light-transmitting hole.

Referring to FIGS. 7A, 7B and 7D, the outer contour of the first light-transmitting sub-hole 41 includes a first curved border B1 and a second curved border B2; the first curved border B1 and the first line segment M1 form a semicircle; the second curved border B2 and the first line segment M1 form a semiellipse; and a center of the semicircle of the first light-transmitting sub-hole 41 coincides with a center of a corresponding first electrode block 211.

In addition, the outer contour of the second light-transmitting sub-hole 42 is substantially in a shape of a circle, and a center of the circle coincides with a center of a corresponding second electrode block 212. The outer contour of the third light-transmitting sub-hole 43 is substantially in a shape of a circle, and a center of the circle coincides with a center of a corresponding first electrode block 211.

In the virtual quadrilateral, among two first light-transmitting sub-holes 41 respectively located on two opposite sides in the first direction X, a semicircular portion of one first light-transmitting sub-hole 41 is located on a side of a corresponding elliptical portion in the second direction Y, and a semicircular portion of another first light-transmitting sub-hole 41 is located on another side of a corresponding elliptical portion in the second direction Y; among two first light-transmitting sub-holes 41 respectively located on two opposite sides in the second direction Y, a semicircular portion of one first light-transmitting sub-hole 41 is located on a side of a corresponding elliptical portion in the first direction X, and a semicircular portion of another first light-transmitting sub-hole 41 is located on another side of a corresponding elliptical portion in the first direction X.

In this case, in a 400 pixels per inch (PPI) display panel 100, a minimum radial size of the first light-transmitting hole 40 is in a range of 19 μm to 21 μm, and a minimum distance between the first light-transmitting hole 40 and the electrode block 210 is in a range of 5.3 μm to 7.3 μm.

It should be noted that the 400 PPI display panel 100 is only taken as an example for illustration here. The minimum radial size of the first light-transmitting hole 40 and the minimum distance between the first light-transmitting hole 40 and the electrode block 210 vary corresponding to different PPI display panels 100, which will be specifically determined according to the parameter requirements of the display panels 100.

A distance between a boundary of the first light-transmitting sub-hole 41 and a boundary of a corresponding connection hole 301 (see FIG. 3A or 3B) is in a range of 18.38 μm to 20.38 μm. A distance between a boundary of the second light-transmitting sub-hole 42 and a boundary of a corresponding connection hole 301 is in a range of 13 μm to 15 μm. A distance between a boundary of the third light-transmitting sub-hole 43 and a boundary of a corresponding connection hole 301 is in a range of 21.27 μm to 23.27 μm.

It should be noted that the 400 PPI display panel 100 is only taken as an example for illustration here. The distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 vary corresponding to different PPI display panels 100, as long as the distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 are each greater than or equal to a second preset value. As for the description of the connection hole 301 and the second preset value, reference may be made to the following description, and details will not be provided here in the embodiments of the present disclosure.

In addition, a minimum distance between the boundary of the first light-transmitting sub-hole 41 and the boundary of the second light-transmitting sub-hole 42 is in a range of 20 μm to 22 μm, and a minimum distance between the boundary of the second light-transmitting sub-hole 42 and the boundary of the third light-transmitting sub-hole 43 is in a range of 22.83 μm to 24.83 μm.

It should be noted that the 400 PPI display panel 100 is only taken as an example for illustration here. The minimum distance between the boundaries of the first light-transmitting sub-hole 41 and the second light-transmitting sub-hole 42 and the minimum distance between the boundaries of the second light-transmitting sub-hole 42 and the third light-transmitting sub-hole 43 vary corresponding to different PPI display panels 100, which will be specifically determined according to the parameter requirements of the display panels 100.

An aperture ratio of the first light-transmitting sub-hole 41 is in a range of 5.24% to 7.24%, an aperture ratio of the second light-transmitting sub-hole 42 is in a range of 2.79% to 4.79%, and an aperture ratio of the third light-transmitting sub-hole 43 is in a range of 3.46% to 5.46%. In the case where a pixel unit includes one first light-transmitting sub-hole 41, two second light-transmitting sub-holes 42 and one third light-transmitting sub-hole 43, a total aperture ratio of the sub-pixel P is in a range of 14.28% to 22.28%.

It should be noted that the 400 PPI display panel 100 is only taken as an example for illustration here. The aperture ratios of the first light-transmitting sub-hole 41, the second light-transmitting sub-hole 42 and the third light-transmitting sub-hole 43 vary corresponding to different PPI display panels 100, which will be specifically determined according to the parameter requirements of the display panels 100.

For another example, as shown in FIGS. 7C and 7E, the first light-transmitting sub-hole 41 is the set light-transmitting hole, and the third light-transmitting sub-hole 43 is the non-set light-transmitting hole.

Referring to FIGS. 7A, 7C and 7E, the outer contour of the third light-transmitting sub-hole 43 includes a first curved border B1 and a second curved border B2; the first curved border B1 and the first line segment M1 form a semicircle; the second curved border B2 and the first line segment M1 form a semiellipse; and a center of the semicircle of the third light-transmitting sub-hole 43 coincides with a center of a corresponding first electrode block 211.

In addition, the outer contour of the second light-transmitting sub-hole 42 is substantially in a shape of a circle, and a center of the circle coincides with a center of a corresponding second electrode block 212. The outer contour of the first light-transmitting sub-hole 41 is substantially in a shape of a circle, and a center of the circle coincides with a center of a corresponding first electrode block 211.

In the virtual quadrilateral, among two third light-transmitting sub-holes 43 respectively located on two opposite sides in the first direction X, a semicircular portion of one third light-transmitting sub-hole 43 is located on a side of a corresponding elliptical portion in the second direction Y, and a semicircular portion of another third light-transmitting sub-hole 43 is located on another side of a corresponding elliptical portion in the second direction Y; among two third light-transmitting sub-holes 43 respectively located on two opposite sides in the second direction Y, a semicircular portion of one third light-transmitting sub-hole 43 is located on a side of a corresponding elliptical portion in the first direction X, and a semicircular portion of another third light-transmitting sub-hole 43 is located on another side of a corresponding elliptical portion in the first direction X.

In this case, in the 400 pixels per inch (PPI) display panel 100, a minimum radial size of the first light-transmitting hole 40 is in a range of 19 μm to 21 μm, and a minimum distance between the first light-transmitting hole 40 and the electrode block 210 is in a range of 5.3 μm to 7.3 μm.

It should be noted that the 400 PPI display panel 100 is only taken as an example for illustration here. The minimum radial size of the first light-transmitting hole 40 and the minimum distance between the first light-transmitting hole 40 and the electrode block 210 vary corresponding to different PPI display panels 100, which will be specifically determined according to the parameter requirements of the display panels 100.

A distance between a boundary of the first light-transmitting sub-hole 41 and a boundary of a corresponding connection hole 301 is in a range of 18.69 μm to 20.69 μm.

A distance between a boundary of the second light-transmitting sub-hole 42 and a boundary of a corresponding connection hole 301 is in a range of 12.42 μm to 14.42 μm. A distance between a boundary of the third light-transmitting sub-hole 43 and a boundary of a corresponding connection hole 301 is in a range of 19.94 μm to 21.94 μm.

It should be noted that the 400 PPI display panel 100 is only taken as an example for illustration here. The distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 vary corresponding to different PPI display panels 100, as long as the distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 are each greater than or equal to the second preset value. As for the description of the connection hole 301 and the second preset value, reference may be made to the following description, and details will not be provided here in the embodiments of the present disclosure.

In addition, a minimum distance between the boundary of the first light-transmitting sub-hole 41 and the boundary of the second light-transmitting sub-hole 42 is in a range of 21.53 μm to 23.53 μm, and a minimum distance between the boundary of the second light-transmitting sub-hole 42 and the boundary of the third light-transmitting sub-hole 43 is in a range of 22.83 μm to 24.83 μm.

It should be noted that the 400 PPI display panel 100 is only taken as an example for illustration here. The minimum distance between the boundaries of the first light-transmitting sub-hole 41 and the second light-transmitting sub-hole 42 and the minimum distance between the boundaries of the second light-transmitting sub-hole 42 and the third light-transmitting sub-hole 43 vary corresponding to different PPI display panels 100, which will be specifically determined according to the parameter requirements of the display panels 100.

An aperture ratio of the first light-transmitting sub-hole 41 is in a range of 5.88% to 7.88%, an aperture ratio of the second light-transmitting sub-hole 42 is in a range of 3.18% to 5.18%, and an aperture ratio of the third light-transmitting sub-hole 43 is in a range of 3.92% to 5.92%. In the case where a pixel unit includes one first light-transmitting sub-hole 41, two second light-transmitting sub-holes 42 and one third light-transmitting sub-hole 43, a total aperture ratio of the sub-pixel P is in a range of 16.16% to 24.16%.

It should be noted that the 400 PPI display panel 100 is only taken as an example for illustration here. The aperture ratios of the first light-transmitting sub-hole 41, the second light-transmitting sub-hole 42 and the third light-transmitting sub-hole 43 vary corresponding to different PPI display panels 100, which will be specifically determined according to the parameter requirements of the display panels 100.

For yet another example, as shown in FIGS. 8B and 8D, the first light-transmitting sub-hole 41 is the non-set light-transmitting hole, and the third light-transmitting sub-hole 43 is the set light-transmitting hole.

Referring to FIGS. 8A, 8B and 8D, the outer contour of the first light-transmitting sub-hole 41 includes a first straight border D1, a second straight border D2 and a third curved border B3. Two ends of the third curved border B3 are respectively connected to the first straight border D1 and the second straight border D2, so as to form a third connection point and a fourth connection point. A midpoint of a line connecting the third connection point and the fourth connection point, i.e., a midpoint of the second line segment M2, coincides with a center of a corresponding first electrode block 211.

In addition, the outer contour of the second light-transmitting sub-hole 42 is substantially in a shape of a rhombus, and a center of the rhombus coincides with a center of a corresponding second electrode block 212. The outer contour of the third light-transmitting sub-hole 43 is substantially in a shape of a rhombus, and a center of the rhombus coincides with a center of a corresponding first electrode block 211.

In the virtual quadrilateral, among two first light-transmitting sub-holes 41 respectively located on two opposite sides in the first direction X, a third curved border B3 of one first light-transmitting sub-hole 41 is located on a side of a corresponding second line segment M2 in the second direction Y, and a third curved border B3 of another first light-transmitting sub-hole 41 is located on another side of a corresponding second line segment M2 in the second direction Y; among two first light-transmitting sub-holes 41 respectively located on two opposite sides in the second direction Y, a third curved border B3 of one first light-transmitting sub-hole 41 is located on a side of a corresponding second line segment M2 in the first direction X, and a third curved border B3 of another first light-transmitting sub-hole 41 is located on another side of a corresponding second line segment M2 in the first direction X.

In this case, in the 400 pixels per inch (PPI) display panel 100, a minimum radial size of the first light-transmitting hole 40 is in a range of 19.68 μm to 21.68 μm, and a minimum distance between the first light-transmitting hole 40 and the electrode block 210 is in a range of 3 μm to 3.2 μm.

It should be noted that the 400 PPI display panel 100 is only taken as an example for illustration here. The minimum radial size of the first light-transmitting hole 40 and the minimum distance between the first light-transmitting hole 40 and the electrode block 210 vary corresponding to different PPI display panels 100, which will be specifically determined according to the parameter requirements of the display panels 100.

A distance between a boundary of the first light-transmitting sub-hole 41 and a boundary of a corresponding connection hole 301 is in a range of 14.9 μm to 16.9 μm, a distance between a boundary of the second light-transmitting sub-hole 42 and a boundary of a corresponding connection hole 301 is in a range of 10 μm to 12 μm, and a distance between a boundary of the third light-transmitting sub-hole 43 and a boundary of a corresponding connection hole 301 is in a range of 18.1 μm to 20.1 μm.

It should be noted that the 400 PPI display panel 100 is only taken as an example for illustration here. The distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 vary corresponding to different PPI display panels 100, as long as the distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 are each greater than or equal to a second preset value. As for the description of the connection hole 301 and the second preset value, reference may be made to the following description, and details will not be provided here in the embodiments of the present disclosure.

In addition, a minimum distance between the boundary of the first light-transmitting sub-hole 41 and the boundary of the second light-transmitting sub-hole 42 is in a range of 20 μm to 22 μm, and a minimum distance between the boundary of the second light-transmitting sub-hole 42 and the boundary of the third light-transmitting sub-hole 43 is in a range of 22 μm to 24 μm.

It should be noted that the 400 PPI display panel 100 is only taken as an example for illustration here. The minimum distance between the boundaries of the first light-transmitting sub-hole 41 and the second light-transmitting sub-hole 42 and the minimum distance between the boundaries of the second light-transmitting sub-hole 42 and the third light-transmitting sub-hole 43 vary corresponding to different PPI display panels 100, which will be specifically determined according to the parameter requirements of the display panels 100.

An aperture ratio of the first light-transmitting sub-hole 41 is in a range of 7.48% to 9.48%, an aperture ratio of the second light-transmitting sub-hole 42 is in a range of 4.15% to 6.15%, and an aperture ratio of the third light-transmitting sub-hole 43 is in a range of 5.06% to 7.06%. In the case where a pixel unit includes one first light-transmitting sub-hole 41, two second light-transmitting sub-holes 42 and one third light-transmitting sub-hole 43, a total aperture ratio of the sub-pixel P is in a range of 20.84% to 28.84%.

It should be noted that the 400 PPI display panel 100 is only taken as an example for illustration here. The aperture ratios of the first light-transmitting sub-hole 41, the second light-transmitting sub-hole 42 and the third light-transmitting sub-hole 43 vary corresponding to different PPI display panels 100, which will be specifically determined according to the parameter requirements of the display panels 100.

For yet another example, as shown in FIGS. 8C and 8E, the first light-transmitting sub-hole 41 is the set light-transmitting hole, and the third light-transmitting sub-hole 43 is the non-set light-transmitting hole.

Referring to FIGS. 8A, 8C and 8E, the outer contour of the third light-transmitting sub-hole 43 includes a first straight border D1, a second straight border D2 and a third curved border B3. Two ends of the third curved border B3 are respectively connected to the first straight border D1 and the second straight border D2, so as to form a third connection point and a fourth connection point. A midpoint of a line connecting the third connection point and the fourth connection point, i.e., a midpoint of the second line segment M2, coincides with a center of a corresponding first electrode block 211.

In addition, the outer contour of the second light-transmitting sub-hole 42 is substantially in a shape of a rhombus, and a center of the rhombus coincides with a center of a corresponding second electrode block 212. The outer contour of the first light-transmitting sub-hole 41 is substantially in a shape of a rhombus, and a center of the rhombus coincides with a center of a corresponding first electrode block 211.

In the virtual quadrilateral, among two third light-transmitting sub-holes 43 respectively located on two opposite sides in the first direction X, a third curved border B3 of one third light-transmitting sub-hole 43 is located on a side of a corresponding second line segment M2 in the second direction Y, and a third curved border B3 of another third light-transmitting sub-hole 43 is located on another side of a corresponding second line segment M2 in the second direction Y; among two third light-transmitting sub-holes 43 respectively located on two opposite sides in the second direction Y, a third curved border B3 of one third light-transmitting sub-hole 43 is located on a side of a corresponding second line segment M2 in the first direction X, and a third curved border B3 of another third light-transmitting sub-hole 43 is located on another side of a corresponding second line segment M2 in the first direction X.

In this case, in the 400 pixels per inch (PPI) display panel 100, a minimum radial size of the first light-transmitting hole 40 is in a range of 19.68 μm to 21.68 μm, and a minimum distance between the first light-transmitting hole 40 and the electrode block 210 is in a range of 3 μm to 3.2 μm.

It should be noted that the 400 PPI display panel 100 is only taken as an example for illustration here. The minimum radial size of the first light-transmitting hole 40 and the minimum distance between the first light-transmitting hole 40 and the electrode block 210 vary corresponding to different PPI display panels 100, which will be specifically determined according to the parameter requirements of the display panels 100.

A distance between a boundary of the first light-transmitting sub-hole 41 and a boundary of a corresponding connection hole 301 is in a range of 15.16 μm to 17.16 μm, a distance between a boundary of the second light-transmitting sub-hole 42 and a boundary of a corresponding connection hole 301 is in a range of 9.7 μm to 11.7 μm, and a distance between a boundary of the third light-transmitting sub-hole 43 and a boundary of a corresponding connection hole 301 is in a range of 17.6 μm to 19.6 μm.

It should be noted that the 400 PPI display panel 100 is only taken as an example for illustration here. The distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 vary corresponding to different PPI display panels 100, as long as the distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 are each greater than or equal to a second preset value. As for the description of the connection hole 301 and the second preset value, reference may be made to the following description, and details will not be provided here in the embodiments of the present disclosure.

In addition, a minimum distance between the boundary of the first light-transmitting sub-hole 41 and the boundary of the second light-transmitting sub-hole 42 is in a range of 20 μm to 22 μm, and a minimum distance between the boundary of the second light-transmitting sub-hole 42 and the boundary of the third light-transmitting sub-hole 43 is in a range of 24.56 μm to 26.56 μm.

It should be noted that the 400 PPI display panel 100 is only taken as an example for illustration here. The minimum distance between the boundaries of the first light-transmitting sub-hole 41 and the second light-transmitting sub-hole 42 and the minimum distance between the boundaries of the second light-transmitting sub-hole 42 and the third light-transmitting sub-hole 43 vary corresponding to different PPI display panels 100, which will be specifically determined according to the parameter requirements of the display panels 100.

An aperture ratio of the first light-transmitting sub-hole 41 is in a range of 7.45% to 9.45%, an aperture ratio of the second light-transmitting sub-hole 42 is in a range of 4.13% to 6.13%, and an aperture ratio of the third light-transmitting sub-hole 43 is in a range of 5.04% to 7.04%. In the case where a pixel unit includes one first light-transmitting sub-hole 41, two second light-transmitting sub-holes 42 and one third light-transmitting sub-hole 43, a total aperture ratio of the sub-pixel P is in a range of 20.75% to 28.75%.

It should be noted that the 400 PPI display panel 100 is only taken as an example for illustration here. The aperture ratios of the first light-transmitting sub-hole 41, the second light-transmitting sub-hole 42 and the third light-transmitting sub-hole 43 vary corresponding to different PPI display panels 100, which will be specifically determined according to the parameter requirements of the display panels 100.

For yet another example, as shown in FIGS. 9B and 9D, the first light-transmitting sub-hole 41 is the set light-transmitting hole, and the third light-transmitting sub-hole 43 is the non-set light-transmitting hole.

Referring to FIGS. 9A, 9B and 9D, the outer contour of each of the third light-transmitting sub-holes 43 is substantially in a shape of a circle, and a center of the circle does not coincide with a center of a corresponding first electrode block 211.

In addition, the outer contour of the second light-transmitting sub-hole 42 is substantially in a shape of a circle, and a center of the circle coincides with a center of a corresponding second electrode block 212. The outer contour of the first light-transmitting sub-hole 41 is substantially in a shape of a circle, and a center of the circle coincides with a center of a corresponding first electrode block 211.

In the virtual quadrilateral, among two third light-transmitting sub-holes 43 respectively located on two opposite sides in the first direction X, a center of a circle of one third light-transmitting sub-hole 43 is located on a side of a center of a corresponding first electrode block 211 in the second direction Y, and a center of a circle of another third light-transmitting sub-hole 43 is located on another side of a center of a corresponding first electrode block 211 in the second direction Y; among two third light-transmitting sub-holes 43 respectively located on two opposite sides in the second direction Y, a center of a circle of one third light-transmitting sub-hole 43 is located on a side of a center of a corresponding first electrode block 211 in the first direction X, and a center of a circle of another third light-transmitting sub-hole 43 is located on another side of a center of a corresponding first electrode block 211 in the first direction X.

In this case, in the 400 pixels per inch (PPI) display panel 100, a minimum radial size of the first light-transmitting hole 40 is in a range of 19 μm to 21 μm, and a minimum distance between the first light-transmitting hole 40 and the electrode block 210 is in a range of 5.5 μm to 7.5 μm.

It should be noted that the 400 PPI display panel 100 is only taken as an example for illustration here. The minimum radial size of the first light-transmitting hole 40 and the minimum distance between the first light-transmitting hole 40 and the electrode block 210 vary corresponding to different PPI display panels 100, which will be specifically determined according to the parameter requirements of the display panels 100.

A distance between a boundary of the first light-transmitting sub-hole 41 and a boundary of a corresponding connection hole 301 is in a range of 19.12 μm to 21.12 μm, a distance between a boundary of the second light-transmitting sub-hole 42 and a boundary of a corresponding connection hole 301 is in a range of 12.34 μm to 14.34 μm, and a distance between a boundary of the third light-transmitting sub-hole 43 and a boundary of a corresponding connection hole 301 is in a range of 20.4 μm to 22.4 μm.

It should be noted that the 400 PPI display panel 100 is only taken as an example for illustration here. The distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 vary corresponding to different PPI display panels 100, as long as the distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 are each greater than or equal to a second preset value. As for the description of the connection hole 301 and the second preset value, reference may be made to the following description, and details will not be provided here in the embodiments of the present disclosure.

In addition, a minimum distance between the boundary of the first light-transmitting sub-hole 41 and the boundary of the second light-transmitting sub-hole 42 is in a range of 20 μm to 22 μm, and a minimum distance between the boundary of the second light-transmitting sub-hole 42 and the boundary of the third light-transmitting sub-hole 43 is in a range of 22 μm to 24 μm.

It should be noted that the 400 PPI display panel 100 is only taken as an example for illustration here. The minimum distance between the boundaries of the first light-transmitting sub-hole 41 and the second light-transmitting sub-hole 42 and the minimum distance between the boundaries of the second light-transmitting sub-hole 42 and the third light-transmitting sub-hole 43 vary corresponding to different PPI display panels 100, which will be specifically determined according to the parameter requirements of the display panels 100.

An aperture ratio of the first light-transmitting sub-hole 41 is in a range of 5.82% to 7.82%, an aperture ratio of the second light-transmitting sub-hole 42 is in a range of 3.12% to 5.12%, and an aperture ratio of the third light-transmitting sub-hole 43 is in a range of 3.87% to 5.87%. In the case where a pixel unit includes one first light-transmitting sub-hole 41, two second light-transmitting sub-holes 42 and one third light-transmitting sub-hole 43, a total aperture ratio of the sub-pixel P is in a range of 15.97% to 23.97%.

It should be noted that the 400 PPI display panel 100 is only taken as an example for illustration here. The aperture ratios of the first light-transmitting sub-hole 41, the second light-transmitting sub-hole 42 and the third light-transmitting sub-hole 43 vary corresponding to different PPI display panels 100, which will be specifically determined according to the parameter requirements of the display panels 100.

For yet another example, as shown in FIGS. 9C and 9E, the first light-transmitting sub-hole 41 is the non-set light-transmitting hole, and the third light-transmitting sub-hole 43 is the set light-transmitting hole.

Referring to FIGS. 9A, 9C and 9E, the outer contour of each of the first light-transmitting sub-holes 41 is substantially in a shape of a circle, and a center of the circle does not coincide with a center of a corresponding first electrode block 211.

In addition, the outer contour of the second light-transmitting sub-hole 42 is substantially in a shape of a circle, and a center of the circle coincides with a center of a corresponding second electrode block 212. The outer contour of the third light-transmitting sub-hole 43 is substantially in a shape of a circle, and a center of the circle coincides with a center of a corresponding first electrode block 211.

In the virtual quadrilateral, among two first light-transmitting sub-holes 41 respectively located on two opposite sides in the first direction X, a center of a circle of one first light-transmitting sub-hole 41 is located on a side of a center of a corresponding first electrode block 211 in the second direction Y, and a center of a circle of another first light-transmitting sub-hole 41 is located on another side of a center of a corresponding first electrode block 211 in the second direction Y; among two first light-transmitting sub-holes 41 respectively located on two opposite sides in the second direction Y, a center of a circle of one first light-transmitting sub-hole 41 is located on a side of a center of a corresponding first electrode block 211 in the first direction X, and a center of a circle of another first light-transmitting sub-hole 41 is located on another side of a center of a corresponding first electrode block 211 in the first direction X.

In this case, in the 400 pixels per inch (PPI) display panel 100, a minimum radial size of the first light-transmitting hole 40 is in a range of 19 μm to 21 μm, and a minimum distance between the first light-transmitting hole 40 and the electrode block 210 is in a range of 5.5 μm to 7.5 μm.

It should be noted that the 400 PPI display panel 100 is only taken as an example for illustration here. The minimum radial size of the first light-transmitting hole 40 and the minimum distance between the first light-transmitting hole 40 and the electrode block 210 vary corresponding to different PPI display panels 100, which will be specifically determined according to the parameter requirements of the display panels 100.

A distance between a boundary of the first light-transmitting sub-hole 41 and a boundary of a corresponding connection hole 301 is in a range of 18.7 μm to 20.7 μm, a distance between a boundary of the second light-transmitting sub-hole 42 and a boundary of a corresponding connection hole 301 is in a range of 12.65 μm to 14.65 μm, and a distance between a boundary of the third light-transmitting sub-hole 43 and a boundary of a corresponding connection hole 301 is in a range of 20.78 μm to 22.78 μm.

It should be noted that the 400 PPI display panel 100 is only taken as an example for illustration here. The distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 vary corresponding to different PPI display panels 100, as long as the distance between the boundary of the first light-transmitting sub-hole 41 and the boundary of the connection hole 301, the distance between the boundary of the second light-transmitting sub-hole 42 and the boundary of the connection hole 301, and the distance between the boundary of the third light-transmitting sub-hole 43 and the boundary of the connection hole 301 are each greater than or equal to a second preset value. As for the description of the connection hole 301 and the second preset value, reference may be made to the following description, and details will not be provided here in the embodiments of the present disclosure.

In addition, a minimum distance between the boundary of the first light-transmitting sub-hole 41 and the boundary of the second light-transmitting sub-hole 42 is in a range of 20 μm to 22 μm, and a minimum distance between the boundary of the second light-transmitting sub-hole 42 and the boundary of the third light-transmitting sub-hole 43 is in a range of 22 μm to 24 μm.

It should be noted that the 400 PPI display panel 100 is only taken as an example for illustration here. The minimum distance between the boundaries of the first light-transmitting sub-hole 41 and the second light-transmitting sub-hole 42 and the minimum distance between the boundaries of the second light-transmitting sub-hole 42 and the third light-transmitting sub-hole 43 vary corresponding to different PPI display panels 100, which will be specifically determined according to the parameter requirements of the display panels 100.

An aperture ratio of the first light-transmitting sub-hole 41 is in a range of 5.82% to 7.82%, an aperture ratio of the second light-transmitting sub-hole 42 is in a range of 3.12% to 5.12%, and an aperture ratio of the third light-transmitting sub-hole 43 is in a range of 3.87% to 5.87%. In the case where a pixel unit includes one first light-transmitting sub-hole 41, two second light-transmitting sub-holes 42 and one third light-transmitting sub-hole 43, a total aperture ratio of the sub-pixel P is in a range of 15.97% to 23.97%.

It should be noted that the 400 PPI display panel 100 is only taken as an example for illustration here. The aperture ratios of the first light-transmitting sub-hole 41, the second light-transmitting sub-hole 42 and the third light-transmitting sub-hole 43 vary corresponding to different PPI display panels 100, which will be specifically determined according to the parameter requirements of the display panels 100.

In some embodiments, referring to FIGS. 3A, 4 and 5, the first electrode layer 20 further includes a plurality of connection strips 220, and the plurality of connection strips 220 include a plurality of first connection strips 221 and a plurality of second connection strips 222. Each first connection strip 221 is electrically connected to a first electrode block 211, and each second connection strip 222 is electrically connected to a second electrode block 212.

As shown in FIG. 6, in the second direction Y, a single first connection strip 221 and a single second connection strip 222 are arranged between each two adjacent first electrode blocks 211. In this case, the first connection strip 221 and the second connection strip 222 are concentratedly arranged, which facilitates the arrangement of the first electrode block 211 and the second electrode block 212.

Here, the connection strip 220 is substantially in a shape of a long strip. On this basis, a length of the first connection strip 221 is greater than or equal to 7.9 μm, and a width of the first connection strip 221 is greater than or equal to 4.6 μm. For example, a length of the second connection strip is any one of 7.9 μm, 8 μm, 8.1 μm, 8.2 μm, and 8.3 μm, and a width of the second connection strip is any one of 4.6 μm, 4.7 μm, 4.8 μm, 4.9 μm, and 5 μm.

It will be noted that, the term “substantially in a shape of a long strip” herein means in a shape of a long strip as a whole, but is not limited to a standard shape of a long strip. That is, “shape of a long strip” herein includes not only a substantial shape of a long strip but also a shape similar to a long strip in consideration of process conditions. For example, corners of a long strip are curved, that is, the corners are smooth.

In some embodiments, referring to FIGS. 3A and 14, the display panel 100 further includes a first planarization layer 30, and the first planarization layer 30 is in contact with a surface of the first electrode layer 20 proximate to the substrate 10.

The first planarization layer 30 is provided therein with connection holes 301. Each first connection strip 221 extends into a corresponding connection hole 301, and each second connection strip 222 extends into a corresponding connection hole 301.

Here, a minimum distance between an orthogonal projection of a boundary of the connection hole 301 on the substrate 10 and an orthogonal projection of a boundary of the first light-transmitting hole 40 on the substrate 10 is greater than or equal to a second preset value, so that a part of the electrode block 210 (see FIG. 4) exposed by the first light-transmitting hole 40 has a large distance from the connection hole 301. Therefore, the flatness of the part of the electrode block 210 exposed by the first light-transmitting hole 40 is high, and the flatness of the light-emitting device 2 is improved, which makes the display brightness of the display panel 100 more uniform.

It will be noted that the second preset value may be in a range of 8.5 μm to 11.5 μm. For example, the second preset value is any one of 8.5 μm, 9 μm, 9.5 μm, 10 μm, 10.5 μm, 11 μm, and 11.5 μm.

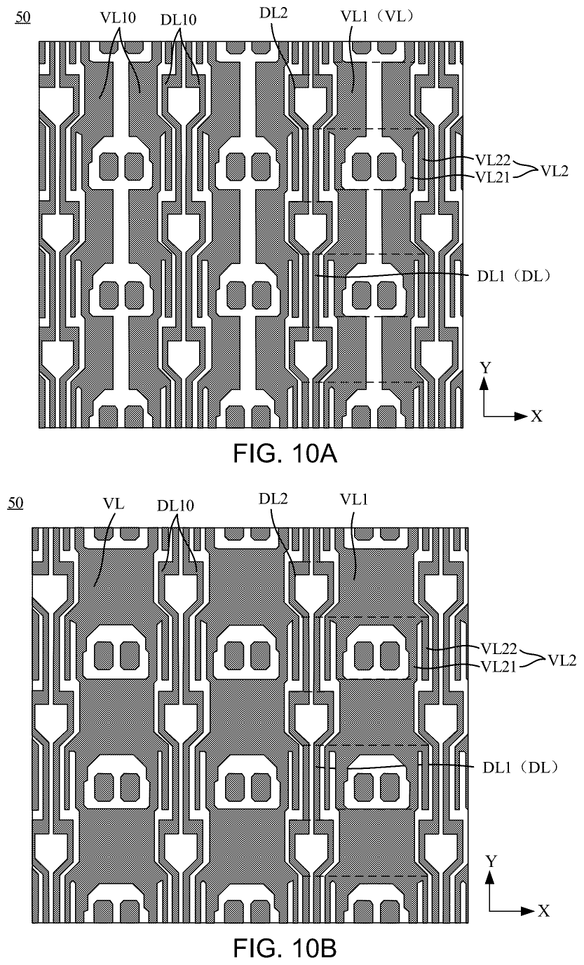

In some embodiments, referring to FIGS. 3A and 10A, the display panel 100 further includes at least one conductive layer 50. The at least one conductive layer 50 is disposed between the substrate 10 and the first electrode layer 20.

The at least one conductive layer 50 includes a plurality of first power signal lines VL substantially extending in the second direction Y. The first power signal lines VL are configured to transmit first power voltage signals Vdd.

On this basis, as shown in FIGS. 3A, 10A and 11, an orthogonal projection of at least one first electrode block 211 on the substrate 10 overlaps with an orthographic projection of at least one first power signal line VL on the substrate 10. A region where the orthogonal projection of the first electrode block 211 on the substrate 10 overlaps with the orthographic projection of the first power signal line VL on the substrate 10 is symmetrical with respect to the median line of the first electrode block 211 in the second direction Y.

In this way, when the first power signal line VL passes under the first electrode block 211, a part of the first power signal line VL directly under the first electrode block 211 is symmetrical with respect to the median line of the first electrode block 211 in the second direction Y. Therefore, it may be possible to balance heights of two sides of the median line in the second direction Y of the first electrode block 211, improve the flatness of the first electrode block 211, and improve the display effect.

In some examples, referring to FIG. 10A, the plurality of first power signal lines VL include a plurality of first power signal line groups VL10, and each first power signal line group VL10 includes two first power signal lines VL arranged in parallel.

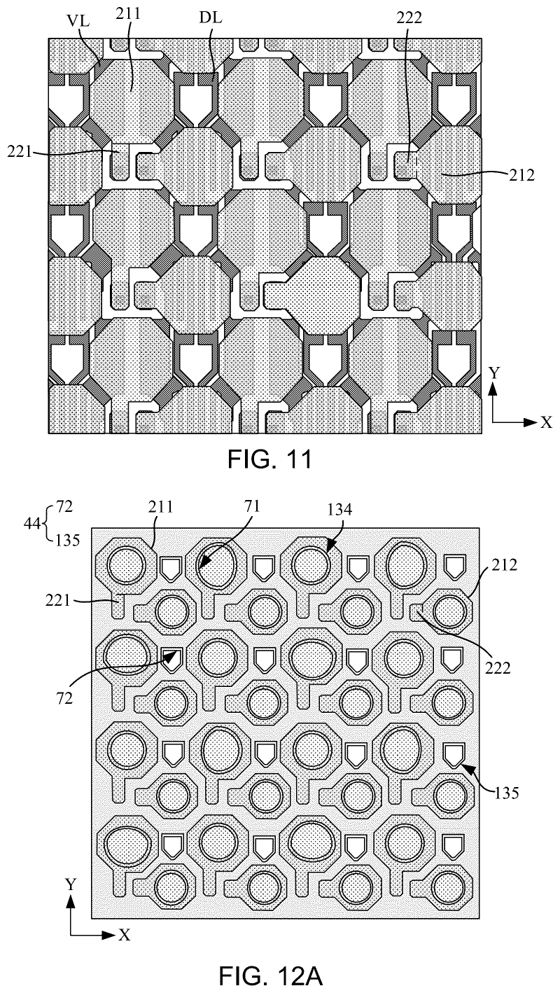

As shown in FIGS. 10A and 11, an orthogonal projection of a column of first electrode blocks 211 arranged in the second direction Y on the substrate 10 (see FIG. 3A) overlaps with each of orthogonal projections of two first power signal lines VL in a first power signal line group VL10 on the substrate 10 (see FIG. 3A); and the two first power signal lines VL in the first power signal line group VL10 are symmetrical with respect to a median line of the column of first electrode blocks 211 in the second direction Y.

In this way, it is conducive to improving the regularity of the arrangement of the first power signal lines VL; and every two first power signal lines VL are arranged in a concentrated manner, so that a spacing between first power signal line groups VL10 is large, which is helpful to avoid other structures (e.g., a functional device mentioned below that need to sense the external ambient light).

In some other examples, referring to FIG. 10B, an orthogonal projection of a column of first electrode blocks 211 arranged in the second direction Y on the substrate 10 (see FIG. 3A) overlaps with an orthogonal projection of a first power signal line VL on the substrate 10 (see FIG. 3A); and the first power signal line VL is symmetrical with respect to a median line of the column of first electrode blocks 211 in the second direction Y.

In this way, it is conducive to improving the regularity of the arrangement of the first power signal lines VL, increasing sectional areas of the first power signal lines VL, and reducing the resistance.

In some embodiments, referring to FIGS. 3A, 10A and 11, an orthogonal projection of at least one second electrode block 212 on the substrate 10 overlaps with an orthogonal projection of at least one first power signal line VL1 on the substrate 10; and a region where orthogonal projections of the second electrode block 212 and the first power signal line VL1 on the substrate 10 overlap is symmetrical with respect to the median line of the second electrode block 212 in the second direction Y.

In this way, a part of the first power signal line VL directly under the second electrode block 212 is symmetrical with respect to the median line of the second electrode block 212 in the second direction Y. Therefore, it may be possible to balance heights of two sides of the median line in the second direction Y of the second electrode block 212, improve the flatness of the second electrode block 212, and improve the display effect.

In some examples, referring to FIG. 10A, the plurality of first power signal lines VL include a plurality of first power signal line groups VL10, and each first power signal line group VL10 includes two first power signal lines VL arranged in parallel.

As shown in FIGS. 10A and 11, an orthogonal projection of a column of second electrode blocks 212 arranged in the second direction Y on the substrate 10 (see FIG. 3A) overlaps with each of orthogonal projections of two first power signal lines VL close to each other in two adjacent first power signal line groups VL10 on the substrate 10 (see FIG. 3A); and the two first power signal lines VL close to each other are symmetrical with respect to a median line of the column of second electrode blocks 212 in the second direction Y.

In this way, it is conducive to improving the regularity of the arrangement of the first power signal lines VL; and every two first power signal lines VL are arranged in a concentrated manner, so that a spacing between first power signal line groups VL10 is large, which is helpful to avoid other structures (e.g., a functional device mentioned below that need to sense the external ambient light).

In some other examples, referring to FIG. 10B, an orthogonal projection of a column of second electrode blocks 212 arranged in the second direction Y on the substrate 10 (see FIG. 3A) overlaps with each of orthogonal projections of two adjacent first power signal lines VL on the substrate 10 (see FIG. 3A); and the two adjacent first power signal lines VL are symmetrical with respect to a median line of the column of second electrode blocks 212 in the second direction Y.

In this way, it is conducive to improving the regularity of the arrangement of the first power signal lines VL, increasing the sectional areas of the first power signal lines VL, and reducing the resistance.

It should be understood that the electrode block 210 is electrically connected to the pixel circuit 3 through the connection strip 220, which means that the connection strip 220 cannot be short-circuited with other signal line(s). Based on this, the first power signal line VL should avoid the connection strip 220.

In some embodiments, referring to FIGS. 10A and 10B, the first power signal line VL includes first line portions VL1 and second line portions VL2.

As shown in FIGS. 3A, 10A, 10B and 11, an orthogonal projection of the first line portion VL1 on the substrate 10 is located within the orthogonal projection of the first electrode block 211 on the substrate 10. The second line portion VL2 is located between two adjacent first electrode blocks 211 in the second direction Y.

It should be noted that, in the first direction X, a distance between a boundary of the first line portion VL1 and a boundary of the first electrode block 211 is greater than or equal to 2.5 μm.

As shown in FIGS. 3A, 10A and 11, in the case where the orthogonal projection of a column of first electrode blocks 211 arranged in the second direction Y on the substrate 10 overlaps with each of the orthogonal projections of the two first power signal lines VL in a first power signal line group VL10 on the substrate 10, orthogonal projections of a single first connection strip 221 and a single second connection strip 222 on the substrate 10 are located between orthogonal projections of second line portions VL2 of two first power signal lines VL in a single first power signal line group VL10 on the substrate 10.

Here, an orthogonal projection of the second line portion VL2 on the substrate 10 partially overlaps with an orthogonal projection of a nearest column of second electrode blocks 212 on the substrate 10.

For example, as shown in FIG. 10A, the second line portion VL2 includes a body portion VL21 and a support portion VL22. Orthogonal projections of the body portion VL21 and the support portion VL22 on the substrate 10 all overlap with an orthogonal projection of a second electrode block 212 on the substrate 10.

Two ends of the body portion VL21 are electrically connected to first line portions VL1, respectively. The support portion VL22 is located on a side of the body portion VL21 proximate to a median line of the nearest column of second electrode blocks 212 in the second direction Y. Therefore, it is possible to increase an overlapping area of the orthogonal projection of the second line portion VL2 on the substrate 10 (see FIG. 3A) and the orthogonal projection of the second electrode block 212 on the substrate 10 (see FIG. 3A) and in turn improve the flatness of the second electrode block 212.

As shown in FIGS. 3A, 10B and 11, in the case where the orthogonal projection of a column of first electrode blocks 211 arranged in the second direction Y on the substrate 10 overlaps with the orthogonal projection of a first power signal line VL on the substrate 10, the first power signal line VL is provided with a plurality of hollow regions arranged in the second direction Y; and orthogonal projections of a first connection strip 221 and a second connection strip 222 on the substrate 10 are located within an orthogonal projection of a hollow region on the substrate 10.

Here, the orthogonal projection of the second line portion VL2 on the substrate 10 partially overlaps with orthogonal projections of two adjacent columns of second electrode blocks 212 on the substrate 10.

For example, as shown in FIG. 10B, the second line portion VL2 includes a body portion VL21 and support portions VL22. Orthogonal projections of the body portion VL21 and the support portions VL22 on the substrate 10 all overlap with an orthogonal projection of a second electrode block 212 on the substrate 10.

Two ends of the body portion VL21 are electrically connected to first line portions VL1, respectively. The support portions VL22 are located on two opposite sides of the body portion VL21, respectively. Therefore, it is possible to increase an overlapping area of the orthogonal projection of the second line portion VL2 on the substrate 10 (see FIG. 3A) and the orthogonal projection of the second electrode block 212 on the substrate 10 (see FIG. 3A) and in turn improve the flatness of the second electrode block 212.

In some embodiments, referring to FIG. 10A, the at least one conductive layer 50 further includes a plurality of data lines DL substantially extending in the second direction Y. The data lines DL are configured to transmit data signals Data.

On this basis, as shown in FIGS. 3A, 10A and 11, an orthogonal projection of at least one second electrode block 212 on the substrate 10 overlaps with an orthogonal projection of at least one data line DL on the substrate 10; and a region where orthogonal projections of the second electrode block 212 and the data line DL on the substrate 10 overlap is symmetrical with respect to the median line of the second electrode block 212 in the second direction Y.

In this way, when the data line DL passes under the second electrode block 212, a part of the data line DL directly under the second electrode block 212 is symmetrical with respect to the median line of the second electrode block 212 in the second direction Y. Therefore, it may be possible to balance heights of two sides of the median line in the second direction Y of the second electrode block 212, improve the flatness of the second electrode block 212, and improve the display effect.

For example, referring to FIG. 10A, the plurality of data lines DL include a plurality of data line groups DL10, and each data line group DL10 includes two data lines DL arranged in parallel.

As shown in FIGS. 3A, 10A and 11, an orthogonal projection of a column of second electrode blocks 212 arranged in the second direction Y on the substrate 10 at least partially overlaps with each of orthogonal projections of two data lines DL in a data line group DL10 on the substrate 10; and the two data lines DL in the data line group DL10 are symmetrical with respect to a median line the column of second electrode blocks 212 in the second direction.

In some embodiments, the display panel 100 further includes a functional device. The functional device is required to collect the external ambient light, and is integrated on the non-light-exit side of the display panel 100. Here, the functional device may include a fingerprint recognition unit, a photosensitive device, and other functional components.

On this basis, referring to FIG. 7B, the light-emitting definition layer 4 further has a plurality of second light-transmitting holes 44. An orthogonal projection of each second light-transmitting hole 44 on the substrate 10 (see FIG. 3A) is located between orthogonal projections of adjacent second electrode blocks 212 in the second direction Y on the substrate 10 (see FIG. 3A). Therefore, the functional device may collect the external ambient light through the second light-transmitting holes 44.

In some examples, referring to FIGS. 3A and 12B, the light-emitting definition layer 4 includes a pixel definition layer 70. The pixel definition layer 70 is provided therein with a plurality of second openings 72. The second light-transmitting hole 44 includes a second opening 72 in the pixel definition layer 70. The second opening 72 defines a light-transmitting region of the second light-transmitting hole 44.

In some other examples, referring to FIGS. 3A and 12C, the light-emitting definition layer 4 includes a black matrix 132. The black matrix 132 is provided therein with a plurality of fourth openings 135. The second light-transmitting hole 44 includes a fourth opening 135. The fourth opening 135 defines a light-transmitting region of the second light-transmitting hole 44.

In still some other examples, referring to FIGS. 3A and 12D, the light-emitting definition layer 4 includes a pixel definition layer 70 and a black matrix 132. The pixel definition layer 70 is provided therein with a plurality of second openings 72, and the black matrix 132 is provided therein with a plurality of fourth openings 135. The second light-transmitting hole 44 includes a second opening 72 and a fourth opening 135. The second opening 72 and the fourth opening 135 together define a light-transmitting region of the second light-transmitting hole 44.

Here, referring to FIGS. 3A and 12E, a shape of an outer contour of the fourth opening 135 of the black matrix 132 and a shape of an outer contour of the second opening 72 of the pixel definition layer 70 may be the same.

In addition, a size of the fourth opening 135 of the black matrix 132 may be greater than a size of the second opening 72 of the pixel definition layer 70; alternatively, the size of the fourth opening 135 of the black matrix 132 may be smaller than the size of the second opening 72 of the pixel definition layer 70.

For example, referring to FIGS. 3A and 12F, the size of the fourth opening 135 of the black matrix 132 is greater than the size of the second opening 72 of the pixel definition layer 70, and a distance between a boundary of an orthogonal projection of the fourth opening 135 on the substrate 10 and a boundary of an orthogonal projection of the second opening 72 on the substrate 10 is in a range of 2 μm to 6 μm.

It can be understood that, in order to prevent the data lines DL from blocking the second light-transmitting holes 44, the data lines DL need to be arranged to avoid the second light-transmitting holes 44.

In some embodiments, referring to FIG. 10A, the data line DL includes third line portions DL1 and fourth line portions DL2.

As shown in FIGS. 3A, 10A and 11, an orthogonal projection of the third line portion DL1 on the substrate 10 is located within an orthogonal projection of a second electrode block 212 on the substrate 10. The fourth line portion DL2 is located between two adjacent second electrode blocks 212 in the second direction Y.

The orthogonal projection of each second light-transmitting hole 44 on the substrate 10 is located between orthogonal projections of fourth line portions DL2 of two data lines DL in a data line group DL10 on the substrate 10, so as to avoid the data lines DL blocking the second light-transmitting holes 44 to affect the light sensitivity of the functional device.

In addition, in order to increase the area of the second light-transmitting hole 44, two fourth line portions DL2 that are arranged in parallel in a data line group DL10 are bent in directions away from each other to increase the area of the second light-transmitting hole 44.

It can be understood that the first power signal lines VL and the data lines DL may be arranged in the same layer, or may be arranged in different layers. Based on film layer structures of the display panel 100, the above-mentioned at least one conductive layer, first power signal lines VL and data lines DL will be illustrated below by taking an example in which the first power signal lines VL and the data lines DL are arranged in different layers.

As shown in FIG. 3A, in a direction perpendicular to and away from the substrate 10, the display panel 100 includes a semiconductor layer ACT, a first gate conductive layer GT1, a second gate conductive layer GT2, a first source-drain conductive layer SD1, a second source-drain conductive layer SD2, the first planarization layer 30 and the first electrode layer 20 that are arranged in sequence.

It will be noted that, an insulating film layer is provided between each two adjacent layers among the semiconductor layer ACT, the first gate conductive layer GT1, the second gate conductive layer GT2, the first source-drain conductive layer SD1 and the second source-drain conductive layer SD2.

For example, referring to FIG. 3A, the display panel 100 further includes a first gate insulating layer GI1, a second gate insulating layer GI2, an interlayer insulating layer ILD and a second planarization layer 60.

The first gate insulating layer GI1 is disposed between the semiconductor layer ACT and the first gate conductive layer GT1. The second gate insulating layer GI2 is disposed between the first gate conductive layer GT1 and the second gate conductive layer GT2. The interlayer insulating layer ILD is disposed between the second gate conductive layer GT2 and the first source-drain conductive layer SD1. The second planarization layer 60 is disposed between the first source-drain conductive layer SD1 and the second source-drain conductive layer SD2.

On this basis, referring to FIGS. 3A and 10A, the at least one conductive layer 50 includes at least one of: the first gate conductive layer GT1, the second gate conductive layer GT2, the first source-drain conductive layer SD1, or the second source-drain conductive layer SD2.

For example, as shown in FIGS. 3A and 10A, the at least one conductive layer 50 includes the first gate conductive layer GT1, the second gate conductive layer GT2, the first source-drain conductive layer SD1, and the second source-drain conductive layer SD2. In this case, the plurality of data lines DL may be located in the first source-drain conductive layer SD1; and/or the plurality of first power signal lines VL may be located in the second source-drain conductive layer SD2.

In some embodiments, the display panel 100 further includes a third source-drain conductive layer, and the third source-drain conductive layer is located between the first source-drain conductive layer SD1 and the second source-drain conductive layer SD2.

In this case, the at least one conductive layer 50 includes at least one of: the first gate conductive layer GT1, the second gate conductive layer GT2, the first source-drain conductive layer SD1, the third source-drain conductive layer, or the second source-drain conductive layer SD2.

For example, the at least one conductive layer 50 includes the first gate conductive layer GT1, the second gate conductive layer GT2, the first source-drain conductive layer SD1, the third source-drain conductive layer, and the second source-drain conductive layer SD2. In this case, the plurality of data lines DL may be located in the first source-drain conductive layer SD1 and/or the third source-drain conductive layer; and/or the plurality of first power signal lines VL may be located in the second source-drain conductive layer SD2.

In some embodiments, referring to FIGS. 3A, 13 and 14, the display panel 100 further includes the color filter 80, and the color filter 80 is disposed on a side of the light-emitting definition layer 4 away from the substrate 10.

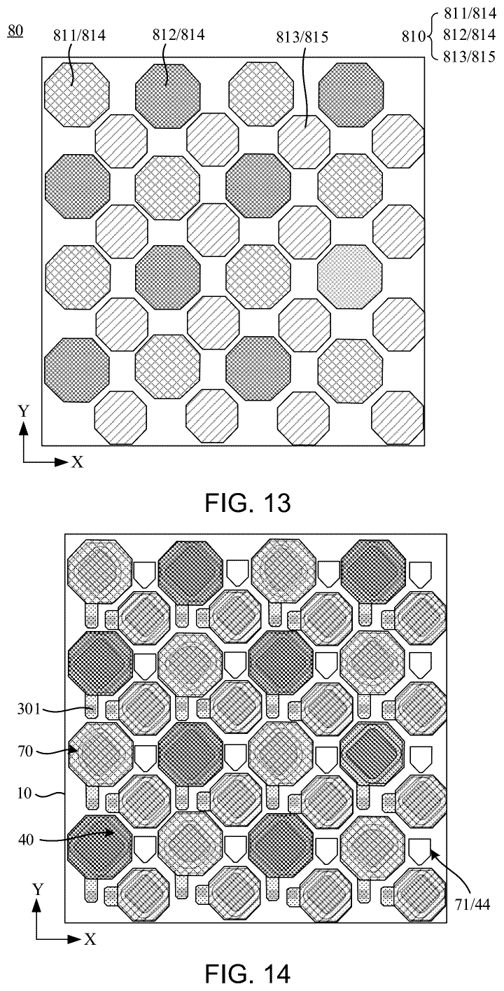

As shown in FIGS. 8C and 13, the color filter 80 includes a plurality of filter portions 810, each filter portion 810 corresponds to a first light-transmitting hole 40 of the light-emitting definition layer 4, and an orthogonal projection of each filter portion 810 on the substrate 10 covers an orthogonal projection of the corresponding first light-transmitting hole 40 on the substrate 10 (see FIG. 3A). Each filter portion 810 is configured to transmit light of a color.

For example, referring to FIGS. 3A, 13 and 14, the orthogonal projection of each filter portion 810 on the substrate 10 covers the orthogonal projection of the corresponding third opening 134 of the black matrix 132 on the substrate 10. The filter portion 810 partially overlaps with the black matrix 132. A distance between a boundary of the filter portion 810 and a boundary of the corresponding third opening 134 is less than or equal to 5 μm.

It will be noted that, the filter portion 810 is made of an organic material. For example, the material of the filter portion 810 includes at least one of: polymethyl methacrylate, general purpose polymers of polystyrene, polymer derivatives with phenol groups, acryloyl-based polymers, imide-based polymers, aryl ether-based polymers, amide-based polymers, fluorine-based polymers, p-xylene-based polymers, or vinyl alcohol-based polymers.

For example, referring to FIG. 2, the plurality of sub-pixels P include first sub-pixels that emit light of a first color, second sub-pixels that emit light of a second color, and third sub-pixels that emit light of a third color. The first color, the second color, and the third color are three primary colors.

On this basis, referring to FIG. 13, based on the colors of light transmitted by the filter portions 810, the plurality of filter portions 810 may include first filter sub-portions 811 transmitting light of the first color, second filter sub-portions 812 transmitting light of the second color, and third filter sub-portions 813 transmitting light of the third color.

In this case, referring to FIGS. 3A, 13 and 14, light emitted by the light-emitting device 2 is incident on a corresponding first filter sub-portion 811 to emit light of the first color; light emitted by the light-emitting device 2 is incident on a corresponding second filter sub-portion 812 to emit light of the second color; light emitted by the light-emitting device 2 is incident on a corresponding third filter sub-portion 813 to emit light of the third color; thereby, the color display is realized.

It will be noted that the light-emitting device 2 may be configured to emit white light or may be configured to emit colored light, which is not specifically limited in the embodiments of the present disclosure.

In some embodiments, referring to FIG. 13, based on shapes of outer contours and areas of the filter portions 810, the plurality of filter portions 810 of the color filter 80 may include a plurality of first filter portions 814 and a plurality of second filter portions 815. An area of the first filter portion 814 is greater than an area of the second filter portion 815.

As shown in FIGS. 11, 13 and 14, an orthogonal projection of a boundary of each first electrode block 211 on the substrate 10 (see FIG. 3A) is located within an orthogonal projection of a boundary of a first filter portion 814 on the substrate 10 (see FIG. 3A). An orthogonal projection of a boundary of each second electrode block 212 on the substrate 10 (see FIG. 3A) is located within an orthogonal projection of a boundary of a second filter portion 815 on the substrate 10 (see FIG. 3A).

That is to say, the color filter 80 provided in the embodiments of the present disclosure may include the first filter portions 814 with larger areas and the second filter portions 815 with smaller areas. In this case, the plurality of filter portions 810 are only provided with two different areas, which may match at least three sub-pixels P with different areas of effective light-emitting regions. In this way, it may be possible to reduce the process difficulty of patterning the color filter 80, and in turn reduce the costs of fabricating the plurality of filter portions 810.

In addition, the shapes and areas of the first filter portions 814 and the second filter portions 815 may be adjusted accordingly to match different types of light-emitting definition layers 4, so as to further reduce the costs of manufacturing display devices 1000 corresponding to different light-emitting definition layers 4.

For example, referring to FIGS. 11 and 13, the shape of the outer contour of the first filter portion 814 may be substantially the same as the shape of the outer contour of the first electrode block 211. The shape of the outer contour of the second filter portion 815 may be substantially the same as the shape of the outer contour of the second electrode block 212.

For example, as shown in FIGS. 3A, 11 and 13, each of the orthogonal projections of the first electrode block 211 and the second electrode block 212 on the substrate 10 is substantially in a shape of a regular octagon. Each of the orthogonal projections of the first filter portion 814 and the second filter portion 815 on the substrate 10 is substantially in a shape of a regular octagon.

It will be noted that, the orthogonal projections of the first filter portion 814 and the second filter portion 815 on the substrate 10 may be substantially in a shape of a circle.

In addition, a distance between any adjacent first filter portion 814 and second filter portion 815 is substantially equal to a third preset value.

Here, the third preset value may be determined according to the process accuracy. For example, the third preset value is in a range of 3.5 μm to 6.5 μm. For example, the third preset value is any one of 3.5 μm, 4 μm, 4.5 μm, 5 μm, 5.5 μm, 6 μm, and 6.5 μm.

In this case, on the plane determined by the first direction X and the second direction Y of the substrate 10, an area utilization ratio of the first filter portions 814 and the second filter portions 815 is high, so that the areas of the first filter portions 814 and the second filter portions 815 are set larger. Therefore, the first light-transmitting holes 40 with smallest areas of various light-emitting definition layers 4 may be sheltered by the first filter portions 814, and other first light-transmitting holes 40 with larger areas may be sheltered by the second filter portions 815, which improves the universality of the color filter 80. As a result, the display devices 1000 corresponding to different light-emitting definition layers 4 may use the above-mentioned color filter 80, to reduce the costs of manufacturing various display devices 1000 corresponding to different light-emitting definition layers 4.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A display panel, comprising:
a substrate;
a first electrode layer disposed on a side of the substrate, wherein the first electrode layer includes a plurality of first electrode blocks and a plurality of second electrode blocks, and an area of a first electrode block is greater than an area of a second electrode block; the plurality of first electrode blocks are arranged in an array of rows and columns, each row includes first electrode blocks arranged in a first direction, and each column includes first electrode blocks arranged in a second direction, the first direction being substantially perpendicular to the second direction; each second electrode block is located between four adjacent first electrode blocks arranged in two rows and two columns; and
a light-emitting definition layer disposed on a side of the first electrode layer away from the substrate, wherein the light-emitting definition layer has a plurality of first light-transmitting holes, at least a part of each first electrode block is exposed by a first light-transmitting hole, and at least a part of each second electrode block is exposed by a first light-transmitting hole; and at least part of a boundary of at least one first light-transmitting hole is curved.

2. The display panel according to claim 1, wherein an outer contour of at least one first light-transmitting hole includes a first curved border and a second curved border, two ends of the first curved border are respectively connected to two ends of the second curved border, and two connection points of the first curved border and the second curved border are a first connection point and a second connection point;
a line connecting the first connection point and the second connection point is a first line segment, a length of the first line segment is a maximum dimension of the first light-transmitting hole, and the first line segment divides the first light-transmitting hole into a first sub-portion including the first curved border and a second sub-portion including the second curved border; and an area of the first sub-portion is greater than an area of the second sub-portion.

3. The display panel according to claim 2, wherein the first curved border and the first line segment enclose a semicircle, and the second curved border and the first line segment enclose a semiellipse.

4. The display panel according to claim 2, wherein the plurality of first light-transmitting holes include a plurality of first light-transmitting sub-holes and a plurality of third light-transmitting sub-holes, and an outer contour of a first light-transmitting sub-hole and/or an outer contour of a third light-transmitting sub-hole includes the first curved border and the second curved border.

5. The display panel according to claim 2, wherein the plurality of first light-transmitting holes include second light-transmitting sub-holes, and an outer contour of a second light-transmitting sub-hole is substantially in a shape of a circle or an ellipse.

6. The display panel according to claim 1, wherein an outer contour of at least one first light-transmitting hole includes a first straight border, a second straight border and a third curved border; the first straight border and the second straight border are connected to form a polyline-shaped border; two ends of the third curved border are respectively connected to two ends of the polyline-shaped border; and two connection points connecting the two ends of the third curved border to the polyline-shaped border are a third connection point and a fourth connection point;
a line connecting the third connection point and the fourth connection point is a second line segment, a length of the second line segment is a maximum dimension of the first light-transmitting hole, and the second line segment divides the first light-transmitting hole into a third sub-portion including the first straight border and the second straight border and a fourth sub-portion including the third curved border; and an area of the third sub-portion is greater than an area of the fourth sub-portion.

7. The display panel according to claim 6, wherein the third curved border includes a first straight sub-line segment, a first curved sub-line segment and a second straight sub-line segment connected in sequence, the first straight sub-line segment is connected to the first straight border, and the second straight sub-line segment is connected to the second straight border; the first straight sub-line segment is substantially parallel to the second straight border, and the second straight sub-line segment is substantially parallel to the first straight border; and/or
the plurality of first light-transmitting holes include a plurality of first light-transmitting sub-holes and a plurality of third light-transmitting sub-holes, and the first light-transmitting sub-holes an outer contour of a first light-transmitting sub-hole and/or an outer contour of a third light-transmitting sub-hole includes the first straight border, the second straight border and the third curved border.

8. The display panel according to claim 6, wherein the plurality of first light-transmitting holes include second light-transmitting sub-holes, and an outer contour of a second light-transmitting sub-hole is substantially in a shape of a rhombus.

9. The display panel according to claim 1, wherein an outer contour of the first light-transmitting hole is substantially in a shape of a circle or an ellipse.

10. The display panel according to claim 1, wherein each of an outer contour of the first electrode block and an outer contour of the second electrode block is substantially in a shape of a polygon;
borders of any adjacent first electrode block and second electrode block are opposite and substantially parallel to each other, and a distance between the adjacent first electrode block and second electrode block is substantially equal to a first preset value, and the first preset value is a process limit value at which the first electrode block and the second electrode block are disconnected.

11. The display panel according to claim 10, wherein each of orthogonal projections of the first electrode block and the second electrode block on the substrate is substantially in a shape of a regular octagon.

12. The display panel according to claim 1, wherein the light-emitting definition layer includes a pixel definition layer, the pixel definition layer is provided therein with a plurality of first openings, and the first light-transmitting hole includes a first opening.

13. The display panel according to claim 12, wherein the light-emitting definition layer further has a plurality of second light-transmitting holes; the pixel definition layer is further provided therein with a plurality of second openings; and a second light-transmitting hole includes a second opening.

14. The display panel according to claim 1, wherein the light-emitting definition layer includes a black matrix, the black matrix is provided therein with a plurality of third openings, and the first light-transmitting hole includes a third opening.

15. The display panel according to claim 14, wherein the light-emitting definition layer further has a plurality of second light-transmitting holes; the black matrix is provided therein with a plurality of fourth openings; and a second light-transmitting hole includes a fourth opening.

16. The display panel according to claim 1, wherein the light-emitting definition layer includes a pixel definition layer and a black matrix; the first light-transmitting hole includes a first opening of the pixel definition layer and a third opening of the black matrix; and a shape of an outer contour of the first opening is the same as a shape of an outer contour of the third opening.

17. The display panel according to claim 16, wherein the light-emitting definition layer further has a plurality of second light-transmitting holes; a second light-transmitting hole includes a second opening of the pixel definition layer and a fourth opening of the black matrix, and a shape of an outer contour of the second opening is the same as a shape of an outer contour of the fourth opening.

18. The display panel according to claim 1, further comprising:
a color filter disposed on a side of the light-emitting definition layer away from the substrate, wherein the color filter includes a plurality of first filter portions and a plurality of second filter portions; an area of a first filter portion is greater than an area of a second filter portion; an orthogonal projection of a boundary of each first electrode block on the substrate is located within an orthogonal projection of a boundary of a single first filter portion on the substrate; and an orthogonal projection of a boundary of each second electrode block on the substrate is located within an orthogonal projection of a boundary of a single second filter portion on the substrate.

19. The display panel according to claim 18, wherein a shape of an outer contour of the first filter portion is substantially the same as a shape of an outer contour of the first electrode block; and a shape of an outer contour of the second filter portion is substantially the same as a shape of an outer contour of the second electrode block.

20. A display device, comprising the display panel according to claim 1.
